(19) United States
(12) Patent Application Publication
(10) Pub. No.: US 2024/0178361 A1
(43) Pub. Date: May 30, 2024

(54) DISPLAY DEVICE AND METHOD OF MANUFACTURING THE SAME

(71) Applicant: LG DISPLAY CO., LTD., Seoul (KR)

(72) Inventors: HyunGon Kim, Seoul (KR); KwangSu Lim, Seoul (KR); Soyoung Lee, Seoul (KR); YoungIn Jang, Seoul (KR)

(73) Assignee: LG DISPLAY CO., LTD., SEOUL (KR)

(21) Appl. No.: 18/389,134

(22) Filed: Nov. 13, 2023

(30) Foreign Application Priority Data
Nov. 25, 2022 (KR) 10-2022-0160363

(51) Int. Cl. H01L 33/62; H01L 25/16

(52) U.S. Cl. CPC H01L 33/62; H01L 25/167; H01L 2933/0066

(57) ABSTRACT

In one aspect, a display device includes a substrate having pixels each including a plurality of sub-pixels; a plurality of light-emitting elements on the plurality of sub-pixels and each including one or more n-type electrodes and a p-type electrode; a first connection electrode on each of the plurality of light-emitting elements of the plurality of sub-pixels and including a concave portion that overlaps the one or more n-type electrodes; and a second connection electrode on each of the plurality of light-emitting elements of the plurality of sub-pixels and including a convex portion that overlaps the p-type electrode. The concave portion and the convex portion extend in a first direction in each of a first subset of the plurality of sub-pixels, and the concave portion and the convex portion extend in a second direction different from the first direction in each of a second subset of the plurality of sub-pixels.

### CROSS-REFERENCE TO RELATED APPLICATIONS

This application claims the priority of Korean Patent Application No. 10-2022-0160363 filed on Nov. 25, 2022, in the Korean Intellectual Property Office, the entire disclosure of which is incorporated herein by reference.

### BACKGROUND

### Field of Disclosure

The present specification relates to a display device and a method of manufacturing the same, and more particularly, to a display device, which uses a light-emitting diode (LED), and a method of manufacturing the same.

### Description of the Background

Display devices used for a monitor of a computer, a TV set, a mobile phone, and the like, can be an organic light-emitting display (OLED) configured to autonomously emit, and a liquid crystal display (LCD) that requires a separate light source.

The range of application of the display devices is diversified from the monitor of the computer and the TV set to personal mobile devices, and studies are being conducted on the display devices having wide display areas and reduced volumes and weights.

Recently, display devices including a light-emitting diode (LED) have attracted attention as possible next-generation display devices. Because a LED is made of an inorganic material instead of an organic material, the LED is more reliable and has a longer lifespan than a liquid crystal display device or an organic light-emitting display device. In addition, a LED may be quickly turned on or off, may have an excellent luminous efficiency, may have high impact resistance, greater stability, and can display high-brightness images.

### SUMMARY

An objective of the present disclosure is to provide a display device in which some of a plurality of light-emitting elements are aligned in a first direction, and the remaining light-emitting elements are aligned in a second direction, such that at least some of the light-emitting elements normally operates even though the light-emitting elements are misaligned. Another objective of the present disclosure is to provide a method of manufacturing such display devices.

Another objective of the present disclosure is to provide a display device in which one of a pair of sub-pixels, which displays the same color, may normally display an image even though a plurality of light-emitting elements is shifted and transferred, and a method of manufacturing the same.

Still another objective of the present disclosure is to provide a display device capable of self-assembling a plurality of light-emitting elements by controlling an alignment direction of the plurality of light-emitting elements, and a method of manufacturing the same.

Objectives of the present disclosure are not limited to the above-mentioned objects, and other objects, which are not mentioned above, may be clearly understood by those skilled in the art from the following descriptions.

In one aspect, a display device includes a substrate having pixels each including a plurality of sub-pixels; a plurality of light-emitting elements on the plurality of sub-pixels and each including one or more n-type electrodes and a p-type electrode; a first connection electrode on each of the plurality of light-emitting elements of the plurality of sub-pixels and including a concave portion that overlaps the one or more n-type electrodes; and a second connection electrode on each of the plurality of light-emitting elements of the plurality of sub-pixels and including a convex portion that overlaps the p-type electrode. The concave portion and the convex portion extend in a first direction in each of a first subset of the plurality of sub-pixels, and the concave portion and the convex portion extend in a second direction different from the first direction in each of a second subset of the plurality of sub-pixels.

In another aspect, each of the pixels includes a pair of first sub-pixels including a first-first sub-pixel and a first-second sub-pixel; a pair of second sub-pixels including a second-first sub-pixel and a second-second sub-pixel; and a pair of third sub-pixels including a third-first sub-pixel and a third-second sub-pixel, wherein the concave portions extend in different direction in the pair of first sub-pixels, the pair of second sub-pixels, and the pair of third sub-pixels.

In another aspect, the concave portion extends in the first direction in any one of the first-first sub-pixel and the first-second sub-pixel, the concave portion extends in the first direction in any one of the second-first sub-pixel and the second-second sub-pixel, and the concave portion extends in the first direction in any one of the third-first sub-pixel and the third-second sub-pixel.

In another aspect, the concave portion and the convex portion extend in the second direction in each of the first-first sub-pixel, the second-first sub-pixel, and the third-first sub-pixel, and the concave portion and the convex portion extend in the first direction in each of the first-second sub-pixel, the second-second sub-pixel, and the third-second sub-pixel.

In another aspect, each of the plurality of light-emitting elements further includes an n-type semiconductor layer having a top surface on which the n-type electrode is disposed; a light-emitting layer on the n-type semiconductor layer; and a p-type semiconductor layer on the light-emitting layer and having a top surface on which the p-type electrode is disposed. In each of a subset of the plurality of light-emitting elements, the top surface of the n-type semiconductor layer has an elliptical shape, and the n-type electrodes are disposed at two opposite ends of the top surface of the n-type semiconductor layer in a major axis direction.

In another aspect, a minor axis of the top surface of the n-type semiconductor layer of each of the subset of the light-emitting elements is disposed in a direction identical to extension directions of the concave portion and the convex portion corresponding to the subset of the light-emitting elements, and a major axis of the top surface of the n-type semiconductor layer on each of the subset of the light-emitting elements is disposed in a direction different from the extension directions of the concave portion and the convex portion corresponding to the subset of the light-emitting elements.

In another aspect, a major axis of the top surface of the n-type semiconductor layer is disposed in the second direction in the light-emitting element that overlaps the concave portion and the convex portion extending in the first direction among the subset of the light-emitting elements.

In another aspect, the display device further includes an insulating layer between the plurality of light-emitting elements and the first connection electrode and between the plurality of light-emitting elements and the second connection electrode. The insulating layer includes a pair of first contact holes that overlaps the n-type electrode and the first connection electrode of each of the plurality of light-emitting elements, and a second contact hole that overlaps the p-type electrode and the second connection electrode of each of the plurality of light-emitting elements.

In another aspect, the concave portion of the first connection electrode is between the pair of first contact holes, and the second contact hole overlaps the convex portion of the second connection electrode.

In one aspect, the method of manufacturing a display device includes self-assembling a plurality of light-emitting elements on an assembling substrate on which a plurality of assembling electrodes is formed; transferring the plurality of light-emitting elements on the assembling substrate to a donor; and transferring the plurality of light-emitting elements of the donor to a plurality of sub-pixels of a display panel. The self-assembling of the plurality of light-emitting elements includes forming an electric field by applying voltages to the plurality of assembling electrodes, and self-assembling the plurality of light-emitting elements on the plurality of assembling electrodes with the electric field.

In another aspect, the plurality of assembling electrodes includes a plurality of first assembling electrodes extending in a first direction and including a first-first assembling electrode and a first-second assembling electrode, a plurality of second assembling electrodes extending in the first direction and including a second-first assembling electrode disposed adjacent to the first-first assembling electrode, and a second-second assembling electrode disposed adjacent to the first-second assembling electrode. The first-first assembling electrode and the second-first assembling electrode are disposed in a staggered manner such that a gap extending in the first direction is formed between the first-first assembling electrode and the second-first assembling electrode, The first-second assembling electrode is disposed to face the second-second assembling electrode such that a gap extending in a second direction perpendicular to the first direction is formed between the first-second assembling electrode and the second-second assembling electrode.

In another aspect, each of a subset of the plurality of light-emitting elements includes an n-type semiconductor layer having a top surface with an elliptical shape; a pair of n-type electrodes at two opposite ends of the n-type semiconductor layer in a major axis direction on a top surface of the n-type semiconductor layer; a light-emitting layer on the n-type semiconductor layer; a p-type semiconductor layer on the light-emitting layer; and a p-type electrode on the p-type semiconductor layer. The self-assembling of the subset of the light-emitting elements includes performing self-assembling so that one of the pair of n-type electrodes overlaps the plurality of first assembling electrodes, and the other one of the pair of n-type electrodes overlaps the plurality of second assembling electrodes.

In another aspect, the pair of n-type electrodes is aligned in the second direction in each of some of the light-emitting elements that are assembled on the first-first assembling electrode and the second-first assembling electrode, and the pair of n-type electrodes is aligned in the first direction in each of the subset of the light-emitting elements that are self-assembled on the first-second assembling electrode and the second-second assembling electrode.

In another aspect, a shape of each of the plurality of light emitting elements corresponds to a shape of each of a plurality of holes in the assembling substrate.

In one aspect, a display device includes a substrate including a plurality of sub-pixels; a plurality of light-emitting elements on the plurality of sub-pixels and each including one or more n-type electrodes and a p-type electrode; and a first connection electrode overlapping the one or more n-types electrodes, and a second connection electrode overlapping the p-type electrode on each of the plurality of light-emitting elements, wherein the second connection electrode overlaps the p-type electrode in different directions in at least two of the plurality of sub-pixels.

In another aspect, the first connection electrode and the second connection electrode have a U-shape where the first connection electrode and the second connection electrode overlap the p-type electrode on each of the plurality of light-emitting elements.

In another aspect, the plurality of sub-pixels are paired and the p-type electrode in each sub-pixel in a given pair of sub-pixels is overlapped in one of the different directions.

In another aspect, the p-type electrode in at least two adjacent sub-pixels are overlapped in a same direction.

In another aspect, the p-type electrode in any two adjacent sub-pixels of the plurality of sub-pixels are overlapped in the different directions.

In another aspect, the plurality of sub-pixels are paired and a light emitting element on sub-pixels of each pair of sub-pixels has a same number of n-type electrodes.

In another aspect, when the sub-pixels of a given pair of sub-pixels has two n-type electrodes, the two n-type electrodes in a first one of the sub-pixels of the given pair are oriented in a first direction and the two-n-type electrodes in a second one of the sub-pixels of the given pair are oriented in a second direction that is different from the first direction.

In another aspect, the first direction and the second direction are different than a respective one of the different directions in which the first connection electrode and the second connection electrode overlap the p-type electrode in the first one of the sub-pixels and the second one of the sub-pixels.

In another aspect, the one or more n-type electrodes have one of a circular shape or an elliptical shape.

In another aspect, the display device further includes a light-emitting layer between the one or more n-type electrodes and the p-type electrode of each of the plurality of light emitting-elements.

In another aspect, the one or more n-type electrodes and the p-type electrode are electrically connected. In another aspect, each of the one or more n-type electrodes can have one a circular shape or an elliptical shape.

In another aspect, the plurality of light emitting elements include a first light emitting element, a second light emitting element, and a third light emitting elements.

In another aspect, the first light emitting element has a circular shape.

In another aspect, the second light emitting element and the third light emitting element have an elliptical shape.

In another aspect, the display device further includes a driving transistor; and at least one insulating layer on the driving transistor.

In another aspect, the at least one insulating layer includes a first insulating portion and a second insulating portion separated by the first connection electrode.

In another aspect, the display device further includes a bonding layer; and a planarization layer, wherein the bonding layer and the planarization layer have a step-wise structure.

The effects according to the present disclosure are not limited to the contents exemplified above, and more various effects are included in the present specification.

### BRIEF DESCRIPTION OF THE DRAWINGS

The above and other aspects, features and other advantages of the present disclosure will be more clearly understood from the following detailed description taken in conjunction with the accompanying drawings, in which:

FIG. 1 is a schematic configuration view of a display device according to an exemplary aspect of the present specification:

FIG. 2A is a partial cross-sectional view of the display device according to some aspects of the present disclosure:

FIG. 2B is a perspective view of a tiled display device according to some aspects of the present disclosure:

FIGS. 3 and 4 are enlarged top plan views of the display device according to some aspects of the present disclosure:

FIGS. 5A to 5C provide a top plan view of light emitting elements of the display device according to some aspects of the present disclosure:

FIG. 6 is a cross-sectional view of the display device according to some aspects of the present disclosure:

FIGS. 7A to 7C are schematic top plan views for explaining a connection relationship between a first connection electrode, a second connection electrode, and a light-emitting element in accordance with a transfer position of the light-emitting element of the display device according to some aspects of the present disclosure; and

FIGS. 8A to 8G are process diagrams for explaining a method of manufacturing the display device according to some aspects of the present disclosure.

### DETAILED DESCRIPTION

Various examples of the present disclosure are discussed in detail below. While specific implementations are discussed, it should be understood that this is done for illustration purposes only. A person skilled in the relevant art will recognize that other components and configurations may be used without parting from the spirit and scope of the disclosure. Thus, the following description and drawings are illustrative and are not to be construed as limiting. Numerous specific details are described to provide a thorough understanding of the disclosure. However, in certain instances, well-known or conventional details are not described in order to avoid obscuring the description. References to one or an embodiment in the present disclosure can be references to the same embodiment or any embodiment; and, such references mean at least one of the embodiments.

The shapes, sizes, ratios, angles, numbers, and the like illustrated in the accompanying drawings for describing the exemplary embodiments of the present disclosure are merely examples, and the present disclosure is not limited thereto. Like reference numerals generally denote like elements throughout the specification. Further, in the following description of the present disclosure, a detailed explanation of known related technologies may be omitted to avoid unnecessarily obscuring the subject matter of the present disclosure. The terms such as “including,” “having,” and “consist of” used herein are generally intended to allow other components to be added unless the terms are used with the term “only”. Any references to singular may include plural unless expressly stated otherwise.

Components are interpreted to include an ordinary error range even if not expressly stated.

When the position relation between two parts is described using the terms such as “on”, “above”, “below”, and “next”, one or more parts may be positioned between the two parts unless the terms are used with the term “immediately” or “directly”.

When an element or layer is disposed “on” another element or layer, another layer or another element may be interposed directly on the other element or therebetween.

Although the terms “first”, “second”, and the like are used for describing various components, these components are not confined by these terms. These terms are merely used for distinguishing one component from the other components. Therefore, a first component to be mentioned below may be a second component in a technical concept of the present disclosure.

Like reference numerals generally denote like elements throughout the specification.

A size and a thickness of each component illustrated in the drawing are illustrated for convenience of description, and the present disclosure is not limited to the size and the thickness of the component illustrated.

The features of various embodiments of the present disclosure may be partially or entirely adhered to or combined with each other and may be interlocked and operated in technically various ways, and the embodiments may be carried out independently of or in association with each other.

Hereinafter, a display device and a method of manufacturing the same according to exemplary embodiments of the present disclosure will be described in detail with reference to accompanying drawings.

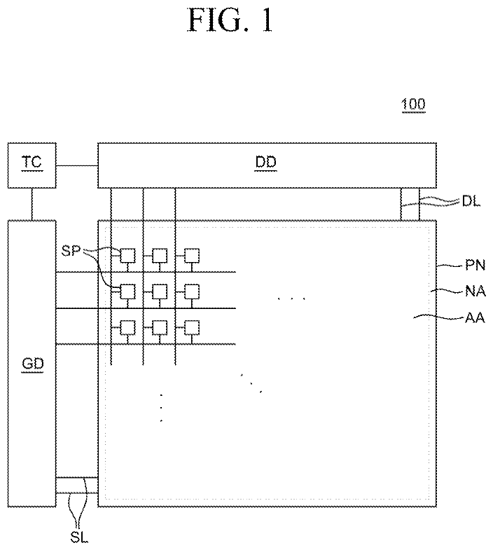

FIG. 1 is a schematic configuration view of a display device according to some aspects of the present disclosure. For convenience of description, FIG. 1 illustrates only a display panel PN, a gate drive part GD, a data drive part DD, and a timing controller TC among various constituent elements of a display device 100.

With reference to FIG. 1, the display device 100 includes the display panel PN including a plurality of sub-pixels SP, the gate drive part GD configured to supply various types of signals to the display panel PN, and the timing controller TC configured to control the data drive part DD, the gate drive part GD, the data drive part DD.

The gate drive part GD supplies a plurality of scan signals to a plurality of scan lines SL in response to a plurality of gate control signals provided from the timing controller TC. FIG. 1 illustrates that the single gate drive part GD is disposed to be spaced apart from one side of the display panel PN. However, the number of and arrangement of the gate drive part GD are not limited thereto.

The data drive part DD converts image data, which are inputted from the timing controller TC, into a data voltage by using a reference gamma voltage in response to a plurality of data control signals provided from the timing controller TC. The data drive part DD may supply the converted data voltage to a plurality of data lines DL.

The timing controller TC aligns image data, which are inputted from the outside, and supplies the image data to the data drive part DD. The timing controller TC may generate the gate control signals and the data control signals by using synchronizing signals, for example, dot clock signals, data enable signals, and horizontal/vertical synchronizing signals inputted from the outside. Further, the timing controller TC may control the gate drive part GD and the data drive part DD by supplying the generated gate control signals and data control signals to the gate drive part GD and the data drive part DD.

The display panel PN is configured to display images to a user and includes the plurality of sub-pixels SP. In the display panel PN, the plurality of scan lines SL, and the plurality of data lines DL intersect one another, and each of the plurality of sub-pixels SP is connected to the scan line SL and the data line DL. In addition, although not illustrated in the drawings, the plurality of sub-pixels SP may be respectively connected to a high-potential power line VDD, a low-potential power line VDD, a reference line, and the like.

The display panel PN may have a display area AA, and a non-display area NA configured to surround the display area AA.

The display area AA is an area of the display device 100 in which images are displayed. The display area AA may include the plurality of sub-pixels SP constituting a plurality of pixels PX, and a circuit configured to operate the plurality of sub-pixels SP. The plurality of sub-pixels SP is minimum units that constitute the display area AA. The n sub-pixels SP may constitute a single pixel PX. A light-emitting element LED, a thin-film transistor for operating the light-emitting element LED, and the like may be disposed in each of the plurality of sub-pixels SP. The plurality of light emitting elements LED may have different configurations depending on the type of display panel PN. For example, in case that the display panel PN is an inorganic light-emitting display panel PN, the light-emitting element LED may be a light-emitting diode (LED) or a micro light-emitting diode (micro LED).

A plurality of signal lines for transmitting various types of signals to the plurality of sub-pixels SP is disposed in the display area AA. For example, the plurality of signal lines may include the plurality of data lines DL for supplying data voltages to the plurality of sub-pixels SP, and the plurality of scan lines SL for supplying gate voltages to the plurality of sub-pixels SP. The plurality of scan lines SL may extend in one direction in the display area AA and be connected to the plurality of sub-pixels SP. The plurality of data lines DL may extend in a direction different from one direction in the display area AA and be connected to the plurality of sub-pixels SP. In addition, the low-potential power line VDD, the high-potential power line VDD, and the like may be further disposed in the display area AA. However, the present disclosure is not limited thereto.

The non-display area NA may be defined as an area in which no image is displayed, i.e., an area extending from the display area AA. The non-display area NA may include link lines and pad electrodes for transmitting signals to the sub-pixels SP in the display area AA. Alternatively, the non-display area NA may include drive ICs such as gate drivers IC and data drivers IC.

In some examples, the non-display area NA may be positioned on a rear surface of the display panel PN, i.e., a surface on which the sub-pixel SP is not present. Alternatively, the non-display area NA may be excluded. However, the present disclosure is not limited to the configuration illustrated in the drawings.

In some examples, the drive parts such as the gate drive part GD, the data drive part DD, and the timing controller TC may be connected to the display panel PN in various ways. For example, the gate drive part GD may be mounted in the non-display area NA by a gate-in-panel (GIP) method or mounted between the plurality of sub-pixels SP by a gate-in-active area (GIA) method in the display area AA. For example, the data drive part DD and the timing controller TC may be formed on a separate flexible film and a printed circuit board and electrically connected to the display panel PN by a method of bonding the flexible film and the printed circuit board to a pad electrode formed in the non-display area NA of the display panel PN. In case that the gate drive part GD is mounted by the GIP method and the data drive part DD and the timing controller TC transmit signals to the display panel PN through the pad electrode in the non-display area NA, it is necessary to ensure an area of the non-display area NA to dispose the gate drive part GD and the pad electrode, which may increase a bezel.

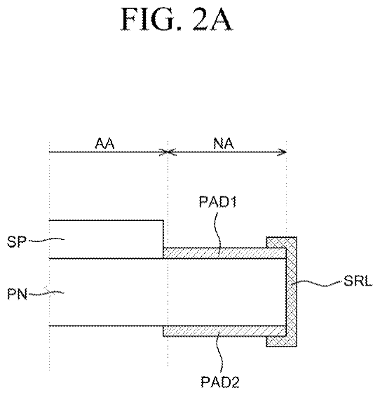

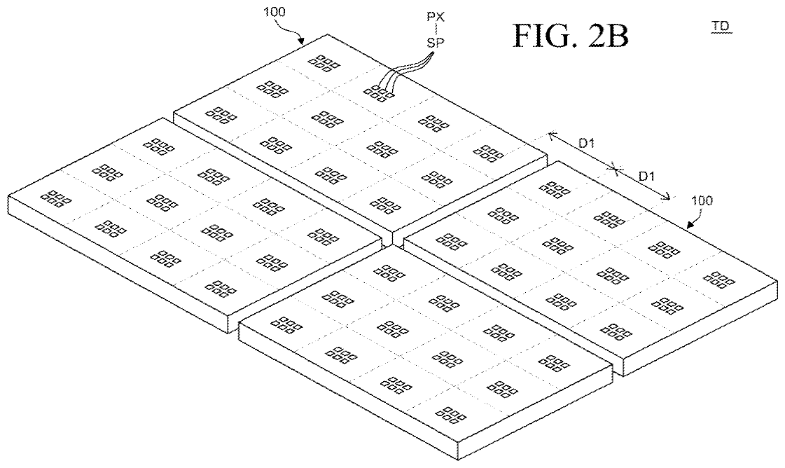

In some examples, the gate drive part GD is mounted in the display area AA by the GIA method and a side line SRL, which connects a signal line on a front surface of the display panel PN to the pad electrode on the rear surface of the display panel PN, is formed to bond the flexible film and the printed circuit board to the rear surface of the display panel PN. Therefore, it would be possible to minimize the non-display area NA on the front surface of the display panel PN. That is, in case that the gate drive part GD, the data drive part DD, and the timing controller TC are connected to the display panel PN by the above-mentioned method, a zero bezel in which the bezel is not substantially present may be implemented. A more detailed description will be described with reference to FIGS. 2A and 2B.

FIG. 2A is a partial cross-sectional view of the display device according to some aspects of the present disclosure. FIG. 2B is a perspective view of a tiled display device according to some aspects of the present disclosure.

A plurality of pad electrodes for transmitting various types of signals to the plurality of sub-pixels SP is disposed in the non-display area NA of the display panel PN. For example, a first pad electrode PAD1 configured to transmit signals to the plurality of sub-pixels SP is disposed in the non-display area NA on the front surface of the display panel PN. A second pad electrode PAD2 electrically connected to drive components such as the flexible film and the printed circuit board is disposed in the non-display area NA on the rear surface of the display panel PN.

In this case, although not illustrated in the drawings, various types of signal lines, e.g., the scan line SL, the data line DL, or the like connected to the plurality of sub-pixels SP may extend from the display area AA to the non-display area NA and be electrically connected to the first pad electrode PAD1.

Further, the side line SRL is disposed along a side surface of the display panel PN. The side line SRL may electrically connect the first pad electrode PAD1 on the front surface of the display panel PN and the second pad electrode PAD2 on the rear surface of the display panel PN. Therefore, the signals received from the drive components on the rear surface of the display panel PN may be transmitted to the plurality of sub-pixels SP through the second pad electrode PAD2, the side line SRL, and the first pad electrode PAD1. Therefore, a signal transmission route is defined from the front surface to the side surface and the rear surface of the display panel PN, which minimizes an area of the non-display area NA of the display panel PN.

Further, with reference to FIG. 2B, a tiled display device TD having a large screen may be implemented by connecting a plurality of display devices 100. In this case, as illustrated in FIG. 2A, in case that the tiled display device TD is implemented by using the display device 100 with the minimized bezel, a seam (blank) area in which no image is displayed between the display devices 100 may be minimized, thereby improving display quality.

For example, the plurality of sub-pixels SP may constitute a single pixel PX. An interval D1 between an outermost peripheral pixel PX of one display device 100 and an outermost peripheral pixel PX of another display device 100 adjacent to one display device 100 may be implemented to be equal to the interval D1 between the pixels PX in one display device 100. Therefore, the seam area may be minimized as a constant interval of the pixels PX is implemented between any two adjacent display devices 100 in a tiled display device TD.

As illustrated in FIG. 2A and FIG. 2B, the display device 100 according to the exemplary aspects of the present specification may be a general display device 100 in which the bezel is present. However, the present disclosure is not limited thereto.

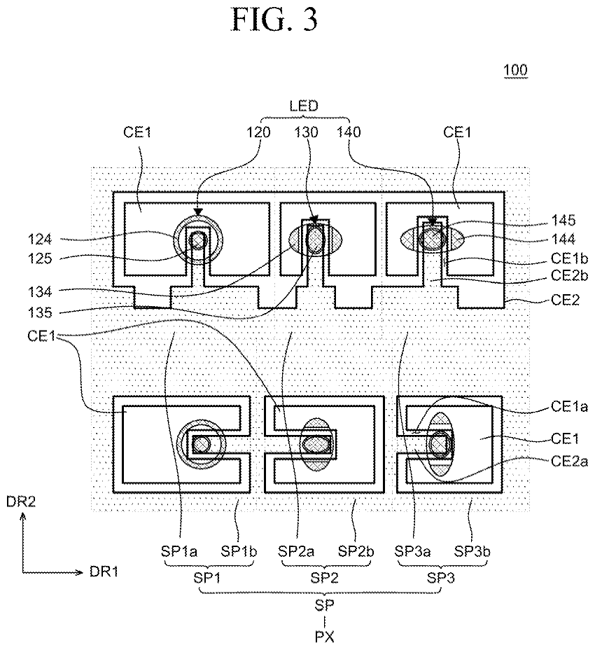

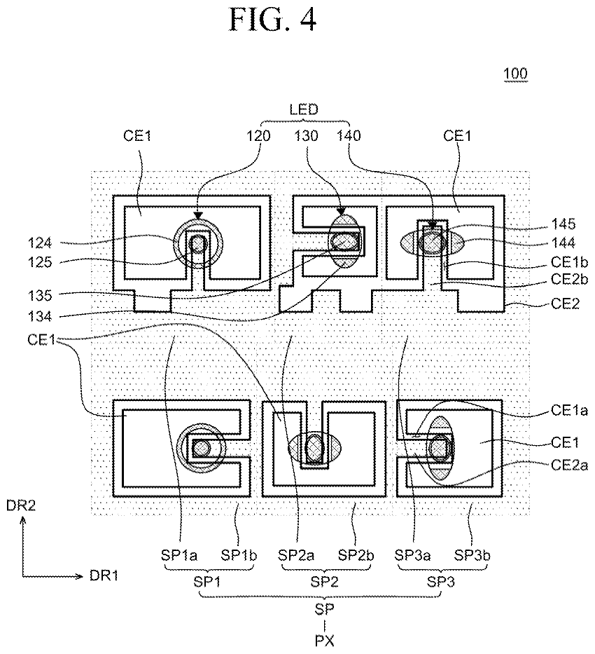

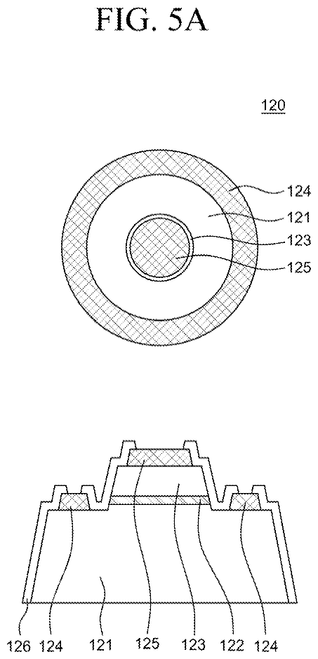

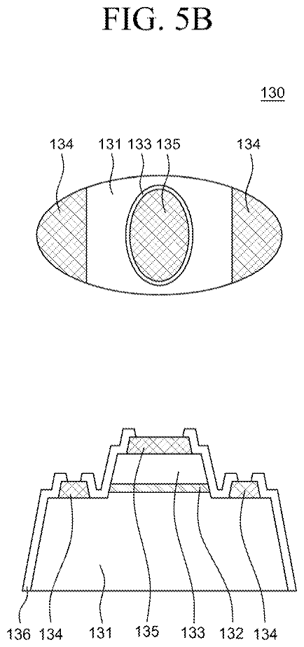

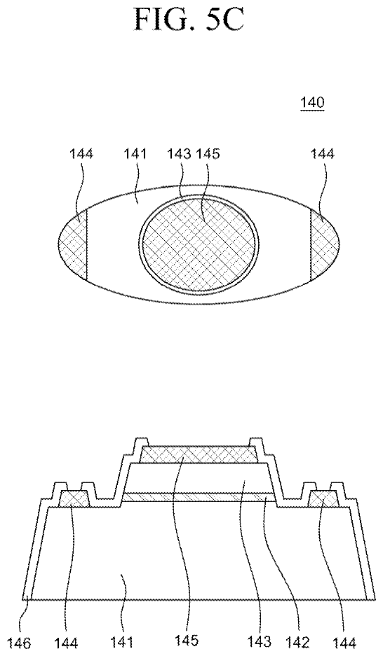

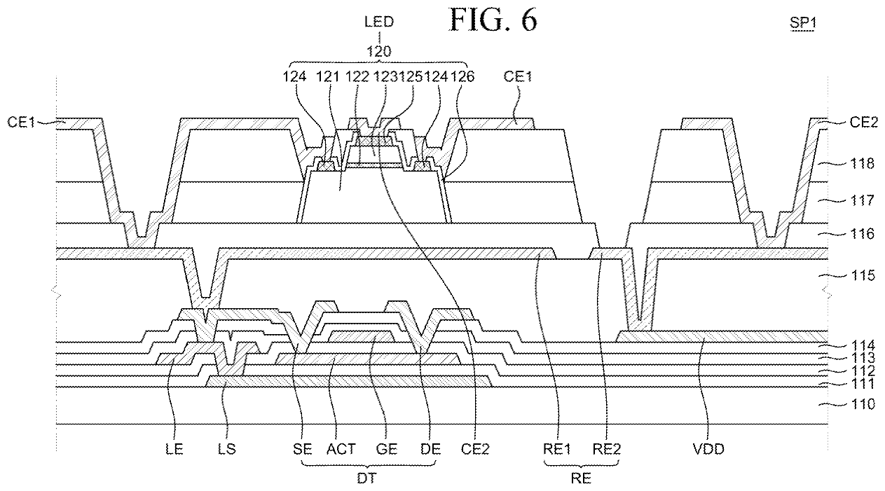

FIGS. 3 and 4 are enlarged top plan views of the display device according to some aspects of the present disclosure. FIG. 5 is a top plan view of a light-emitting element of the display device according to some aspects of the present disclosure. FIG. 6 is a cross-sectional view of the display device according to some aspects of the present disclosure.

First, with reference to FIG. 3, the display panel PN includes the plurality of pixels PX each having the plurality of sub-pixels SP. The plurality of sub-pixels SP may each include the light-emitting element LED and a pixel circuit and independently emit light. For example, the first sub-pixel SP1 may be a red sub-pixel SP, the second sub-pixel SP2 may be a green sub-pixel SP, and the third sub-pixel SP3 may be a blue sub-pixel SP. However, the present disclosure is not limited thereto.

A single pixel PX may include the plurality of sub-pixels SP including the first sub-pixel SP1, the second sub-pixel SP2, and the third sub-pixel SP3. For example, the first sub-pixel SP1 includes a first-first sub-pixel SP1a and a first-second sub-pixel SP1b, the second sub-pixel SP2 includes a second-first sub-pixel SP2a and a second-second sub-pixel SP2b, and the third sub-pixel SP3 includes a third-first sub-pixel SP3a and a third-second sub-pixel SP3b. The first-first sub-pixel SP1a, the second-first sub-pixel SP2a, and the third-first sub-pixel SP3a may be disposed in the same row. The first-second sub-pixel SP1b, the second-second sub-pixel SP2b, and the third-second sub-pixel SP3b may be disposed in the same row.

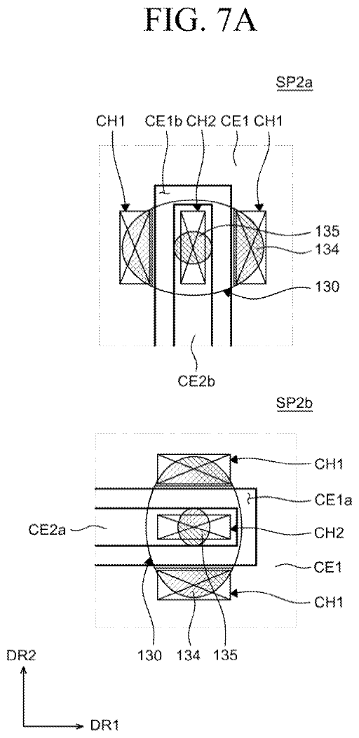

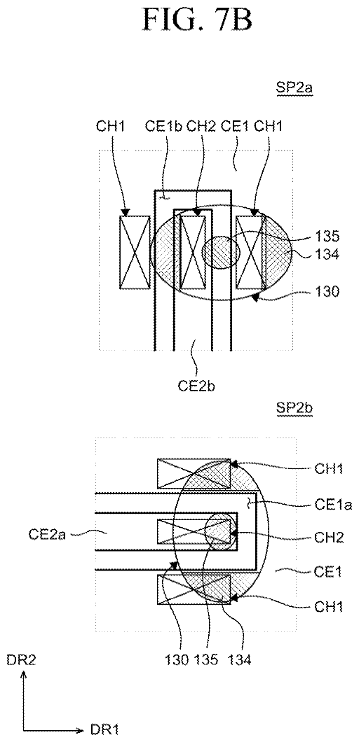

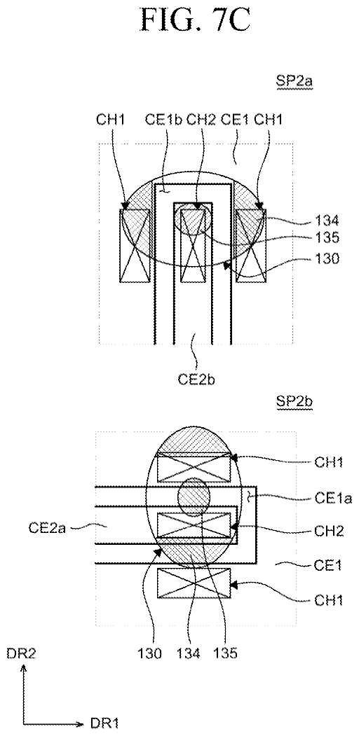

Disposition directions of concave portions CE1a and CE1b of a first connection electrode CE1 and convex portions CE2a and CE2b of a second connection electrode CE2 may be different between the first-first sub-pixel SP1a and the first-second sub-pixel SP1b, between the second-first sub-pixel SP2a and the second-second sub-pixel SP2b, and between the third-first sub-pixel SP3a and the third-second sub-pixel SP3b. In this case, even though the light-emitting elements LED are misaligned, the light-emitting element LED may be normally connected to the first connection electrode CE1 and the second connection electrode CE2 in at least one of a pair of sub-pixels SP. A more detailed description will be described below with reference to FIGS. 7A to 7C.

According to exemplary aspects of the present disclosure and with reference to FIG. 6, each of the plurality of sub-pixels SP of the display panel PN of the display device 100 may include a substrate 110, a buffer layer 111, a gate insulating layer 112, a first interlayer insulating layer 113, a second interlayer insulating layer 114, a first planarization layer 115, a bonding layer 116, a second planarization layer 117, a third planarization layer 118, a driving transistor DT, the light-emitting element LED, a plurality of reflective electrodes RE, a plurality of first connection electrodes CE1, the second connection electrode CE2, a light-blocking layer LS, and an auxiliary electrode LE.

According to some exemplary aspects of the present disclosure, each sub-pixel SP may further include an insulating layer 119 on the driving transistor DT. The insulating layer 119 may further include a first insulating portion 119a and a second insulating portion 119b separated by the plurality of first connection electrodes CE1 and/or the second connection electrode CE2. In some example, each of the first insulating portion 119a and the second insulating portion 119b may cover (e.g., partially) the plurality of first connection electrodes CE1 and/or the second connection electrode CE2.

According to some exemplary aspects of the present disclosure, the bonding layer 116 and the second planarization layer 117 can have a step-wise structure (may also be referred to as a staircase structure). Such structure may be helpful in manufacturing process of creating holes in the first connection electrodes CE1. Without the step-wise structure, making the holes in the first connection electrodes CE1 is likely to result in cracking (breaking) the first connection electrodes CE1.

First, the substrate 110 is a component for supporting various constituent elements included in the display device 100 and may be made of an insulating material. For example, the substrate 110 may be made of glass, resin, or the like. In addition, the substrate 110 may include plastic such as polymer and may be made of a material having flexibility.

The light-blocking layer LS is disposed on each of the plurality of sub-pixels SP on the substrate 110. The light-blocking layer LS blocks light entering an active layer ACT of the driving transistor DT, which will be described below, from a lower side of the substrate 110. The light-blocking layer LS may block light entering the active layer ACT of the driving transistor DT, thereby minimizing a leakage current.

The buffer layer 111 is disposed on the substrate 110 and the light-blocking layer LS. The buffer layer 111 may reduce the penetration of moisture or impurities through the substrate 110. For example, the buffer layer 111 may be configured as a single layer or multilayer made of silicon oxide (SiOx) or silicon nitride (SiNx). However, the present disclosure is not limited thereto. However, the buffer layer 111 may be excluded in accordance with the type of substrate 110 or the type of transistor. However, the present disclosure is not limited thereto.

The driving transistor DT is disposed on the buffer layer 111. The driving transistor DT includes the active layer ACT, a gate electrode GE, a source electrode SE, and a drain electrode DE.

The active layer ACT is disposed on the buffer layer 111. The active layer ACT may be made of a semiconductor material such as an oxide semiconductor, amorphous silicon, or polysilicon. However, the present disclosure is not limited thereto.

The gate insulating layer 112 is disposed on the active layer ACT. The gate insulating layer 112 is an insulating layer for insulating the active layer ACT and the gate electrode GE. The gate insulating layer 112 may be configured as a single layer or multilayer made of silicon oxide (SiOx) or silicon nitride (SiNx). However, the present disclosure is not limited thereto.

The gate electrode GE is disposed on the gate insulating layer 112. The gate electrode GE may be made of an electrically conductive material, for example, copper (Cu), aluminum (Al), molybdenum (Mo), nickel (Ni), titanium (Ti), chromium (Cr), or an alloy thereof. However, the present disclosure is not limited thereto.

The first interlayer insulating layer 113 and the second interlayer insulating layer 114 are disposed on the gate electrode GE. Contact holes, through which the source electrode SE and the drain electrode DE are connected to the active layer ACT, are formed in the first interlayer insulating layer 113 and the second interlayer insulating layer 114. The first interlayer insulating layer 113 and the second interlayer insulating layer 114 may be insulating layers for protecting a lower portion of the first interlayer insulating layer 113 and a lower portion of the second interlayer insulating layer 114 and each configured as a single layer or multilayer made of silicon oxide (SiOx) or silicon nitride (SiNx). However, the present disclosure is not limited thereto.

The source electrode SE and the drain electrode DE are disposed on the second interlayer insulating layer 114 and electrically connected to the active layer ACT. The source electrode SE and the drain electrode DE may each be made of an electrically conductive material, for example, copper (Cu), aluminum (Al), molybdenum (Mo), nickel (Ni), titanium (Ti), chromium (Cr), or an alloy thereof. However, the present disclosure is not limited thereto.

The above description provides an example configuration in which the first interlayer insulating layer 113 and the second interlayer insulating layer 114, i.e., the plurality of insulating layers is disposed between the gate electrode GE, the source electrode SE, and the drain electrode DE. In other non-limiting examples, only a single insulating layer may be disposed between the gate electrode GE, the source electrode SE, and the drain electrode DE. However, the present disclosure is not limited thereto.

Further, as illustrated in the drawings, in case that the plurality of insulating layers, such as the first interlayer insulating layer 113 and the second interlayer insulating layer 114, is disposed between the gate electrode GE, the source electrode SE, and the drain electrode DE, an electrode may be additionally formed between the first interlayer insulating layer 113 and the second interlayer insulating layer 114. The additionally formed electrode may define a capacitor together with other components disposed on the lower portion of the first interlayer insulating layer 113 or the upper portion of the second interlayer insulating layer 114.

The auxiliary electrode LE is disposed on the gate insulating layer 112. The auxiliary electrode LE is an electrode that electrically connects the light-blocking layer LS, which is disposed below the buffer layer 111, to any one of the source electrode SE and the drain electrode DE on the second interlayer insulating layer 114. For example, the light-blocking layer LS may be electrically connected to any one of the source electrode SE or the drain electrode DE through the auxiliary electrode LE so as not to be operated as a floating gate, thereby minimizing a change in threshold voltage of the driving transistor DT caused by the floating light-blocking layer LS. The drawing illustrates that the light-blocking layer LS is connected to the source electrode SE. However, the light-blocking layer LS may be connected to the drain electrode DE. However, the present disclosure is not limited thereto.

A power line VDD is disposed on the second interlayer insulating layer 114. The power line VDD may be electrically connected to the light-emitting element LED together with the driving transistor DT and allow the light-emitting element LED to emit light. The power line VDD may be made of an electrically conductive material, for example, copper (Cu), aluminum (Al), molybdenum (Mo), nickel (Ni), titanium (Ti), chromium (Cr), or an alloy thereof. However, the present disclosure is not limited thereto.

The first planarization layer 115 is disposed on the driving transistor DT and the power line VDD. The first planarization layer 115 may planarize the upper portion of the substrate 110 on which the driving transistor DT is disposed. The first planarization layer 115 may be configured as a single layer or multilayer and made of a photoresist or an acrylic-based organic material, for example. However, the present disclosure is not limited thereto.

The plurality of reflective electrodes RE, which is spaced apart from one another, is disposed on the first planarization layer 115. The plurality of reflective electrodes RE may serve to electrically connect the light-emitting element LED to the power line VDD and the driving transistor DT and serve as a reflective plate that reflects light, which is emitted from the light-emitting element LED, to an upper portion of the light-emitting element LED. The plurality of reflective electrodes RE may each be made of an electrically conductive material having excellent reflection performance and reflect the light, which is emitted from the light-emitting element LED, toward the upper portion of the light-emitting element LED.

The plurality of reflective electrodes RE includes a first reflective electrode RE1 and a second reflective electrode RE2. The first reflective electrode RE1 may electrically connect the driving transistor DT and the light-emitting element LED. The first reflective electrode RE1 may be connected to the source electrode SE or the drain electrode DE of the driving transistor DT through a contact hole formed in the first planarization layer 115. Further, the first reflective electrode RE1 may be electrically connected to a first electrode and a first semiconductor layer of the light-emitting element LED through the first connection electrode CE1 to be described below.

The second reflective electrode RE2 may electrically connect the power line VDD and the light-emitting element LED. The second reflective electrode RE2 may be connected to the power line VDD through a contact hole formed in the first planarization layer 115 and electrically connected to a second electrode and a second semiconductor layer of the light-emitting element LED through the second connection electrode CE2 to be described below.

The bonding layer 116 is disposed on the plurality of reflective electrodes RE. The front surface of the substrate 110 may be coated with the bonding layer 116, and the bonding layer 116 may fix the light-emitting element LED disposed on the bonding layer 116. For example, the bonding layer 116 may be made of any one material selected from adhesive polymer, epoxy resist. UV resin, a polyimide-based material, an acrylate-based material, a urethane-based material, and polydimethylsiloxane (PDMS). However, the present disclosure is not limited thereto.

The plurality of light-emitting elements LED is provided on the bonding layer 116 and disposed on each of the plurality of sub-pixels SP. The plurality of light-emitting elements LED may be elements configured to emit light by using an electric current and include the light-emitting elements LED configured to emit red light, green light, blue light, and the like. The plurality of light-emitting elements LED may implement light with various colors including white by using a combination of red light, green light, blue light, and the like. For example, the plurality of light-emitting elements LED may each be a light-emitting diode (LED) or a micro LED. However, the present disclosure is not limited thereto.

With reference to FIGS. 5A to 5C, the plurality of light-emitting elements LED includes a first light-emitting element 120, a second light-emitting element 130, and a third light-emitting element 140. The first light-emitting element 120 may be disposed on the first sub-pixel SP1, the second light-emitting element 130 may be disposed on the second sub-pixel SP2, and the third light-emitting element 140 may be disposed on the third sub-pixel SP3. For example, the first light-emitting element 120 may be a red light-emitting element LED, the second light-emitting element 130 may be a green light-emitting element LED, and the third light-emitting element 140 may be a blue light-emitting element LED.

With reference to FIGS. 5A and 6, the first light-emitting element 120 includes a first n-type semiconductor layer 121, a first light-emitting layer 122, a second p-type semiconductor layer 123, a first n-type electrode 124, a first p-type electrode 125, and a first sealing film 126.

The first n-type semiconductor layer 121 is disposed on the bonding layer 116, and the first p-type semiconductor layer 123 is disposed on the first n-type semiconductor layer 121. The first n-type semiconductor layer 121 and the first p-type semiconductor layer 123 may each be a layer formed by doping a particular material with n-type and p-type impurities. For example, the first n-type semiconductor layer 121 and the first p-type semiconductor layer 123 may each be a layer formed by doping a material, such as gallium nitride (GaN), indium aluminum phosphide (InAlP), or gallium arsenic (GaAs) with n-type and p-type impurities. Further, the p-type impurity may be magnesium, zinc (Zn), beryllium (Be), or the like. The n-type impurity may be silicon (Si), germanium, tin (Sn), or the like. However, the present disclosure is not limited thereto.

The first light-emitting layer 122 is disposed between the first n-type semiconductor layer 121 and the first p-type semiconductor layer 123. The first light-emitting layer 122 may emit light by receiving positive holes and electrons from the first n-type semiconductor layer 121 and the first p-type semiconductor layer 123. The first light-emitting layer 122 may be configured as a single layer or a multi-quantum well (MQW) structure. For example, the first light-emitting layer 122 may be made of indium gallium nitride (InGaN), gallium nitride (GaN), or the like. However, the present disclosure is not limited thereto.

The first n-type electrode 124 is disposed on the first n-type semiconductor layer 121. The first n-type electrode 124 is an electrode that electrically connects the driving transistor DT and the first n-type semiconductor layer 121. The first n-type electrode 124 may be disposed on a top surface of the first n-type semiconductor layer 121 exposed from the first light-emitting layer 122 and the first p-type semiconductor layer 123. For example, the first n-type electrode 124 may be disposed around the top surface of the first n-type semiconductor layer 121 and have a circular planar shape. The first n-type electrode 124 may be made of an electrically conductive material, for example, a transparent conductive material such as indium tin oxide (ITO) or indium zinc oxide (IZO) or an opaque conductive material such as titanium (Ti), gold (Au), silver (Ag), copper (Cu), or an alloy thereof. However, the present disclosure is not limited thereto.

The first p-type electrode 125 is disposed on the first p-type semiconductor layer 123. The first p-type electrode 125 may be disposed on a top surface of the first p-type semiconductor layer 123. The first p-type electrode 125 is an electrode that electrically connects the power line VDD and the first p-type semiconductor layer 123. The first p-type electrode 125 may be made of an electrically conductive material, for example, a transparent conductive material such as indium tin oxide (ITO) or indium zinc oxide (IZO) or an opaque conductive material such as titanium (Ti), gold (Au), silver (Ag), copper (Cu), or an alloy thereof. However, the present disclosure is not limited thereto.

Next, the first sealing film 126 is disposed to surround the first n-type semiconductor layer 121, the first light-emitting layer 122, the first p-type semiconductor layer 123, the first n-type electrode 124, and the first p-type electrode 125. The first sealing film 126 may be made of an insulating material and protect the first n-type semiconductor layer 121, the first light-emitting layer 122, and the first p-type semiconductor layer 123. Further, a contact hole, through which the first n-type electrode 124 and the first p-type electrode 125 are exposed, may be formed in the first sealing film 126, such that the first connection electrode CE1, the second connection electrode CE2, the first n-type electrode 124, and the first p-type electrode 125 may be electrically connected.

With reference to FIG. 5B, the second light-emitting element 130 includes a second n-type semiconductor layer 131, a second light-emitting layer 132, a second p-type semiconductor layer 133, second n-type electrodes 134, a second p-type electrode 135, and a second sealing film 136.

The second n-type semiconductor layer 131 is disposed on the bonding layer 116, and the second p-type semiconductor layer 133 is disposed on the second n-type semiconductor layer 131. The second n-type semiconductor layer 131 and the second p-type semiconductor layer 133 may each be a layer formed by doping a particular material with n-type and p-type impurities. For example, the second n-type semiconductor layer 131 and the second p-type semiconductor layer 133 may each be a layer formed by doping a material, such as gallium nitride (GaN), indium aluminum phosphide (InAlP), or gallium arsenic (GaAs) with n-type and p-type impurities. Further, the p-type impurity may be magnesium, zinc (Zn), beryllium (Be), or the like. The n-type impurity may be silicon (Si), germanium, tin (Sn), or the like. However, the present disclosure is not limited thereto.

The second light-emitting layer 132 is disposed between the second n-type semiconductor layer 131 and the second p-type semiconductor layer 133. The second light-emitting layer 132 may emit light by receiving positive holes and electrons from the second n-type semiconductor layer 131 and the second p-type semiconductor layer 133. The second light-emitting layer 132 may be configured as a single layer or a multi-quantum well (MQW) structure. For example, the second light-emitting layer 132 may be made of indium gallium nitride (InGaN), gallium nitride (GaN), or the like. However, the present disclosure is not limited thereto.

The one or more second n-type electrodes 134 are disposed on the second n-type semiconductor layer 131. The second n-type electrode 134 is an electrode that electrically connects the driving transistor DT and the second n-type semiconductor layer 131. The second n-type electrode 134 may be disposed on a top surface of the second n-type semiconductor layer 131 exposed from the second light-emitting layer 132 and the second p-type semiconductor layer 133. For example, the second n-type electrodes 134 may be disposed adjacent to two opposite ends of the top surface of the second n-type semiconductor layer 131 based on a major axis direction on the top surface of the second n-type semiconductor layer 131 having an elliptical planar shape. The second n-type electrode 134 may be made of an electrically conductive material, for example, a transparent conductive material such as indium tin oxide (ITO) or indium zinc oxide (IZO) or an opaque conductive material such as titanium (Ti), gold (Au), silver (Ag), copper (Cu), or an alloy thereof. However, the present disclosure is not limited thereto.

The second p-type electrode 135 is disposed on the second p-type semiconductor layer 133. The second p-type electrode 135 may be disposed on a top surface of the second p-type semiconductor layer 133. The second p-type electrode 135 is an electrode that electrically connects the power line VDD and the second p-type semiconductor layer 133. The second p-type electrode 135 may be made of an electrically conductive material, for example, a transparent conductive material such as indium tin oxide (ITO) or indium zinc oxide (IZO) or an opaque conductive material such as titanium (Ti), gold (Au), silver (Ag), copper (Cu), or an alloy thereof. However, the present disclosure is not limited thereto.

Next, the second sealing film 136 is disposed to surround the second n-type semiconductor layer 131, the second light-emitting layer 132, the second p-type semiconductor layer 133, the second n-type electrode 134, and the second p-type electrode 135. The second sealing film 136 may be made of an insulating material and protect the second n-type semiconductor layer 131, the second light-emitting layer 132, and the second p-type semiconductor layer 133. Further, a contact hole, through which the second n-type electrode 134 and the second p-type electrode 135 are exposed, may be formed in the second sealing film 136, such that the second connection electrode CE2, the second connection electrode CE2, the second n-type electrode 134, and the second p-type electrode 135 may be electrically connected.

With reference to FIG. 5C, the third light-emitting element 140 includes a third n-type semiconductor layer 141, a third light-emitting layer 142, a third p-type semiconductor layer 143, third n-type electrodes 144, a third p-type electrode 145, and a third sealing film 146.

The third n-type semiconductor layer 141 is disposed on the bonding layer 116, and the third p-type semiconductor layer 143 is disposed on the third n-type semiconductor layer 141. The third n-type semiconductor layer 141 and the third p-type semiconductor layer 143 may each be a layer formed by doping a particular material with n-type and p-type impurities. For example, the third n-type semiconductor layer 141 and the third p-type semiconductor layer 143 may each be a layer formed by doping a material, such as gallium nitride (GaN), indium aluminum phosphide (InAlP), or gallium arsenic (GaAs) with n-type and p-type impurities. Further, the p-type impurity may be magnesium, zinc (Zn), beryllium (Be), or the like. The n-type impurity may be silicon (Si), germanium, tin (Sn), or the like. However, the present disclosure is not limited thereto.

The third light-emitting layer 142 is disposed between the third n-type semiconductor layer 141 and the third p-type semiconductor layer 143. The third light-emitting layer 142 may emit light by receiving positive holes and electrons from the third n-type semiconductor layer 141 and the third p-type semiconductor layer 143. The third light-emitting layer 142 may be configured as a single layer or a multi-quantum well (MQW) structure. For example, the third light-emitting layer 142 may be made of indium gallium nitride (InGaN), gallium nitride (GaN), or the like. However, the present disclosure is not limited thereto.

The third n-type electrode 144 is disposed on the third n-type semiconductor layer 141. The third n-type electrode 144 is an electrode that electrically connects the driving transistor DT and the third n-type semiconductor layer 141. The third n-type electrode 144 may be disposed on a top surface of the third n-type semiconductor layer 141 exposed from the third light-emitting layer 142 and the third p-type semiconductor layer 143. For example, the third n-type electrodes 144 may be disposed adjacent to two opposite ends of the top surface of the third n-type semiconductor layer 141 based on the major axis direction on the top surface of the third n-type semiconductor layer 141 having an elliptical planar shape. The third n-type electrode 144 may be made of an electrically conductive material, for example, a transparent conductive material such as indium tin oxide (ITO) or indium zinc oxide (IZO) or an opaque conductive material such as titanium (Ti), gold (Au), silver (Ag), copper (Cu), or an alloy thereof. However, the present disclosure is not limited thereto.

The third p-type electrode 145 is disposed on the third p-type semiconductor layer 143. The third p-type electrode 145 may be disposed on a top surface of the third p-type semiconductor layer 143. The third p-type electrode 145 is an electrode that electrically connects the power line VDD and the third p-type semiconductor layer 143. The third p-type electrode 145 may be made of an electrically conductive material, for example, a transparent conductive material such as indium tin oxide (ITO) or indium zinc oxide (IZO) or an opaque conductive material such as titanium (Ti), gold (Au), silver (Ag), copper (Cu), or an alloy thereof. However, the present disclosure is not limited thereto.

Next, the third sealing film 146 is disposed to surround the third n-type semiconductor layer 141, the third light-emitting layer 142, the third p-type semiconductor layer 143, the third n-type electrode 144, and the third p-type electrode 145. The third sealing film 146 may be made of an insulating material and protect the third n-type semiconductor layer 141, the third light-emitting layer 142, and the third p-type semiconductor layer 143. Further, a contact hole, through which the third n-type electrode 144 and the third p-type electrode 145 are exposed, may be formed in the third sealing film 146, such that a third connection electrode, the second connection electrode CE2, the third n-type electrode 144, and the third p-type electrode 145 may be electrically connected.

Meanwhile, the first light-emitting element 120, the second light-emitting element 130, and the third light-emitting element 140 may have different shapes. The plurality of light-emitting elements LED may each include the n-type semiconductor layers 121, 131, and 141, the light-emitting layers 122, 132, and 142, the p-type semiconductor layers 123, 133, and 143, the n-type electrodes 124, 134, and 144, the p-type electrodes 125, 135, and 145, and the sealing films 126, 136, and 146 in common. However, some components of the plurality of light-emitting elements LED may be different in shape from one another.

For example, all the planar shapes of the first n-type semiconductor layer 121, the first light-emitting layer 122, the second p-type semiconductor layer 133, the first n-type electrode 124, and the first p-type electrode 125 of the first light-emitting element 120 may be circular shapes. Among these components, the first n-type electrode 124 may be configured as a circular electrode having a closed loop shape disposed around the first n-type semiconductor layer 121. The first p-type electrode 125 may have a shape corresponding to the top surface of the first p-type semiconductor layer 123.

For example, the planar shapes of the second n-type semiconductor layer 131, the second p-type semiconductor layer 133, and the second p-type electrode 135 of the second light-emitting element 130 may be elliptical shapes. In this case, the major axis direction of the second n-type semiconductor layer 131 may be different from the major axis direction of the second p-type semiconductor layer 133. For example, when the second n-type semiconductor layer 131 has an elliptical shape having a major axis in a horizontal direction, the second p-type semiconductor layer 133 may have an elliptical shape having a major axis in a vertical direction. Further, the second n-type electrodes 134 may be respectively disposed at the two opposite ends of the second n-type semiconductor layer 131 based on the major axis direction on the top surface of the second n-type semiconductor layer 131. Therefore, the plurality of second n-type electrodes 134 disposed at the two opposite ends of the second n-type semiconductor layer 131 may each have a semicircular shape. Lastly, the second p-type electrode 135 may have an elliptical shape, like the top surface of the second p-type semiconductor layer 133.

In some examples, the planar shapes of the third n-type semiconductor layer 141, the third p-type semiconductor layer 143, and the third p-type electrode 145 of the third light-emitting element 140 may be elliptical shapes. Unlike the second light-emitting element 130, in the third light-emitting element 140, a major axis direction of the third n-type semiconductor layer 141 may be identical to a major axis direction of the third p-type semiconductor layer 143. The third n-type electrodes 144 may be disposed at the two opposite ends of the third n-type semiconductor layer 141 based on the major axis direction on the top surface of the third n-type semiconductor layer 141. The third n-type electrode 144 may have a semicircular shape. Further, the third p-type electrode 145 may have an elliptical shape, like the top surface of the third p-type semiconductor layer 143.

In the display device 100 according to the exemplary aspects of the present specification, the first light-emitting element 120, the second light-emitting element 130, and the third light-emitting element 140 may have different shapes, such that the plurality of light-emitting elements LED may be distinguished. For example, during a process of self-assembling the light-emitting elements LED, the plurality of light-emitting elements LED may be formed in different shapes, such that the plurality of light-emitting elements LED may be self-assembled at positions respectively corresponding to the plurality of sub-pixels SP. However, the shapes of the plurality of light-emitting elements LED are exemplary, and the present disclosure is not limited thereto.

With reference back to FIG. 6, the second planarization layer 117 and the third planarization layer 118 are disposed on the bonding layer 116. The second planarization layer 117 may partially overlap the side surfaces of the plurality of light-emitting elements LED and fix and protect the plurality of light-emitting elements LED. The third planarization layer 118 may be formed to cover an upper portion of the second planarization layer 117 and an upper portion of the light-emitting element LED and have a contact hole through which the n-type electrodes 124, 134, and 144 and the p-type electrodes 125, 135, and 145 of the light-emitting element LED are exposed. The n-type electrodes 124, 134, and 144 and the p-type electrodes 125, 135, and 145 of the light-emitting element LED may be exposed from the third planarization layer 118. The third planarization layer 118 may be partially disposed in areas between the n-type electrodes 124, 134, and 144 and the p-type electrodes 125, 135, and 145, thereby minimizing a short-circuit defect. The second planarization layer 117 and the third planarization layer 118 may each be configured as a single layer or multilayer and made of a photoresist or an acrylic-based organic material, for example. However, the present disclosure is not limited thereto. Above example embodiments describe a configuration in which the second planarization layer 117 and the third planarization layer 118 are disposed. However, the planarization layer may be configured as a single layer. However, the present disclosure is not limited thereto.

The plurality of first connection electrodes CE1 and the second connection electrode CE2 may be disposed on the third planarization layer 118.

The first connection electrodes CE1 are electrodes that are respectively disposed on the plurality of sub-pixels SP and electrically connect the light-emitting elements LED and the driving transistors DT. The first connection electrode CE1 may be connected to the first reflective electrode RE1 through contact holes formed in the third planarization layer 118, the second planarization layer 117, and the bonding layer 116. Therefore, the first connection electrode CE1 may be electrically connected to any one of the source electrode SE and the drain electrode DE of the driving transistor DT through the first reflective electrode RE1. Further, the first connection electrodes CE1 may be connected to the n-type electrodes 124, 134, and 144 of the plurality of light-emitting elements LED through contact holes formed in the third planarization layer 118. Therefore, the first connection electrodes CE1 may electrically connect the driving transistors DT and the n-type electrodes 124, 134, and 144 and the n-type semiconductor layers 121, 131, and 141 of the plurality of light-emitting elements LED.

The second connection electrode CE2 is an electrode that electrically connects the light-emitting element LED and the power line VDD. The second connection electrode CE2 may be connected to the second reflective electrode RE2 through contact holes formed in the third planarization layer 118, the second planarization layer 117, and the bonding layer 116. Therefore, the second connection electrode CE2 may be electrically connected to the power line VDD through the second reflective electrode RE2. Further, the second connection electrodes CE2 may be connected to the p-type electrodes 125, 135, and 145 of the plurality of light-emitting elements LED through contact holes formed in the third planarization layer 118. Therefore, the second connection electrodes CE2 may electrically connect the power lines VDD and the p-type electrodes 125, 135, and 145 and the p-type semiconductor layers 123, 133, and 143 of the plurality of light-emitting elements LED.

In some examples, the first connection electrode CE1, which connects the driving transistor DT and the light-emitting element LED disposed on each of the plurality of sub-pixels SP, may be independently disposed on each of the plurality of sub-pixels SP. Further, the second connection electrodes CE2, which are disposed on each of the plurality of sub-pixels SP and connect the power lines VDD and the light-emitting elements LED, may be connected to each other. That is, because a power voltage of the power line VDD is applied in common to all the plurality of light-emitting elements LED of the plurality of sub-pixels SP, the single second connection electrode CE2 may be disposed on all the plurality of sub-pixels SP.

With reference to FIGS. 3 and 4, the concave portions CE1a and CE1b are formed at portions corresponding to the p-type electrodes 125, 135, and 145 so that the first connection electrodes CE1 of the plurality of sub-pixels SP may be connected only to the n-type electrodes 124, 134, and 144 of the light-emitting elements LED without being connected to the p-type electrodes 125, 135, and 145. The concave portions CE1a and CE1b of the first connection electrodes CE1 may overlap the p-type electrodes 125, 135, and 145 of the plurality of light-emitting elements LED. Further, the second connection electrode CE2 includes the convex portions CE2a and CE2b extending toward the inside of the concave portions CE1a and CE1b and be electrically connected to the p-type electrodes 125, 135, and 145 of the plurality of light-emitting elements LED. The convex portions CE2a and CE2b of the second connection electrode CE2 may overlap the p-type electrodes 125, 135, and 145 of the plurality of light-emitting elements LED.

In this case, the concave portions CE1a and CE1b of the first connection electrode CE1 and the convex portions CE2a and CE2b of the second connection electrode CE2 may be disposed in any one of a first direction DR1 or a second direction DR2. The concave portions CE1a and CE1b of the first connection electrode CE1 includes a first concave portion CE1a disposed in the first direction DR1, and a second concave portion CE1b disposed in the second direction DR2. The convex portions CE2a and CE2b of the second connection electrode CE2 includes a first convex portion CE2a disposed in the first direction DR1, and a second convex portion CE2b disposed in the second direction DR2. Therefore, the first concave portion CE1a and the first convex portion CE2a, which extend in the first direction DR1, may be disposed together on one sub-pixel SP. The second concave portion CE1b and the second convex portion CE2b, which extend in the second direction DR2 different from the first direction DR1, may be disposed together on another sub-pixel SP.

Specifically, the concave portions CE1a and CE1b and the convex portions CE2a and CE2b may be respectively disposed in different directions on the two first sub-pixels SP1. Likewise, the concave portions CE1a and CE1b and the convex portions CE2a and CE2b may be respectively disposed in different directions on the pair of second sub-pixels SP2 and the pair of third sub-pixels SP3.

For example, with reference to FIG. 3, the second concave portions CE1b and the second convex portions CE2b may be disposed on the first-first sub-pixel SP1a, the second-first sub-pixel SP2a, and the third-first sub-pixel SP3a, and the first concave portions CE1a and the first convex portions CE2a may be disposed on the first-second sub-pixel SP1b, the second-second sub-pixel SP2b, and the third-second sub-pixel SP3b.

For example, with reference to FIG. 4, the second concave portions CE1b and the second convex portions CE2b may be disposed on the first-first sub-pixel SP1a, the second-second sub-pixel SP2b, and the third-first sub-pixel SP3a, and the first concave portions CE1a and the first convex portions CE2a may be disposed on the first-second sub-pixel SP1b, the second-first sub-pixel SP2a, and the third-second sub-pixel SP3b.

Further, the two second light-emitting elements 130 and the two third light-emitting elements 140, which are disposed on one pixel PX and have the n-type semiconductor layers 131 and 141 each having an elliptical shape, may be respectively disposed in different directions. The disposition directions of the concave portions CE1a and CE1b and the convex portions CE2a and CE2b may be determined depending on the disposition directions of the second light-emitting element 130 and the third light-emitting element 140.

For example, with reference to FIG. 3, in the second-first sub-pixel SP2a and the third-first sub-pixel SP3a that include the second concave portion CE1b and the second convex portion CE2b extending in the second direction DR2, the second light-emitting element 130 and the third light-emitting element 140 may be configured such that the minor axes of the top surfaces of the n-type semiconductor layers 131 and 141 may be disposed in the second direction DR2, and the major axes of the top surfaces of the n-type semiconductor layers 131 and 141 may be disposed in the first direction DR1. In the second-second sub-pixel SP2b and the third-second sub-pixel SP3b that include the first concave portion CE1a and the first convex portion CE2a extending in the first direction DR1, the second light-emitting element 130 and the third light-emitting element 140 may be configured such that the minor axes of the top surfaces of the n-type semiconductor layers 131 and 141 may be disposed in the first direction DR1, and the major axes of the top surfaces of the n-type semiconductor layers 131 and 141 may be disposed in the second direction DR2. Therefore, in the top surfaces of the n-type semiconductor layers 131 and 141 that have elliptical shapes, the minor axis may be disposed in the direction identical to the extension direction of the concave portions CE1a and CE1b and the convex portions CE2a and CE2b, and the major axis may be disposed in the direction different from the extension direction of the concave portions CE1a and CE1b and the convex portions CE2a and CE2b.

In some examples, in the display device 100 according to the exemplary aspects of the present specification, the concave portions CE1a and CE1b of the first connection electrode CE1 and the convex portions CE2a and CE2b of the second connection electrode CE2 may be disposed in different directions in each of the plurality of sub-pixels SP. Therefore, even though the plurality of light-emitting elements LED is shifted and transferred in any one direction, the light-emitting element LED, the first connection electrode CE1, and the second connection electrode CE2 may be connected in at least one sub-pixel SP. This configuration will be described with reference to FIGS. 7A to 7C.

FIGS. 7A to 7C are schematic top plan views for explaining a connection relationship between the first connection electrode, the second connection electrode, and the light-emitting element in accordance with a transfer position of the light-emitting element of the display device according to some aspects of the present disclosure. FIG. 7A is a top plan view of the second sub-pixel SP2 when the light-emitting element LED is transferred to an exact position. FIG. 7B is a top plan view of the second sub-pixel SP2 when the light-emitting element LED is shifted in the first direction DR1 and transferred. FIG. 7C is a top plan view of the second sub-pixel SP2 when the light-emitting element LED is shifted in the second direction DR2 and transferred. For convenience of description, FIGS. 7A to 7C illustrate the top plan views of the plurality of second sub-pixels SP2. However, substantially similar to the second sub-pixel SP2, in the first sub-pixel SP1 and the third sub-pixel SP3, the first connection electrode CE1 and the second connection electrode CE2 may be connected to the light-emitting element LED.

With reference to FIG. 7A, in case that the second light-emitting element 130 is transferred to the exact position, the second n-type electrodes 134 may be disposed to correspond to first contact holes CH1 and the first connection electrode CE1, and the second p-type electrode 135 may be disposed to correspond to a second contact hole CH2 and the convex portions CE2a and CE2b of the second connection electrode CE2. In this case, the first contact hole CH1 and the second contact hole CH2 are the contact holes of the third planarization layer 118 illustrated in FIG. 6 and may be disposed to correspond to the second n-type electrode 134 and the second p-type electrode 135. The size of the second contact hole CH2 may be larger than the size of the second p-type electrode 135. The size of the second contact hole CH2 may be larger than the size of the portion of the second p-type electrode 135 exposed from the second sealing film 136. The second n-type electrode 134 may be electrically connected to the first connection electrode CE1 through the first contact hole CH1, and the second p-type electrode 135 may be electrically connected to the second connection electrode CE2 through the second contact hole CH2. Therefore, in case that the second light-emitting element 130 is transferred to the exact position, the second light-emitting element 130 may be normally connected to the first connection electrode CE1 and the second connection electrode CE2 in both the second-first sub-pixel SP2a and the second-second sub-pixel SP2b.

With reference to FIG. 7B, during the process of transferring the light-emitting element LED onto the bonding layer 116, an alignment error may occur, and the light-emitting element LED may be shifted from the exact position in the first direction DR1. In case that the second light-emitting element 130 is shifted in the first direction DR1, the second n-type electrode 134 and the second p-type electrode 135 of the second light-emitting element 130, a part of the first contact hole CH1, and a part of the second contact hole CH2 may be misaligned with one another. However, in the concave portions CE1a and CE1b and the convex portions CE2a and CE2b extending in the direction identical to the shift direction of the second light-emitting element 130, at least a part of the first contact hole CH1 and at least a part of the second contact hole CH2 may overlap the second n-type electrode 134 and the second p-type electrode 135 of the second light-emitting element 130 and electrically connect the first connection electrode CE1 and the second connection electrode CE2 to the second light-emitting element 130.

For example, the second concave portion CE1b and the second convex portion CE2b extending in the second direction DR2 are disposed in the second-first sub-pixel SP2a. In this case, when the second light-emitting element 130 is shifted in the first direction DR1, the first contact hole CH1, the second contact hole CH2, the second n-type electrode 134, and the second p-type electrode 135 are misaligned in position, such that the second light-emitting element 130) cannot be connected to the first connection electrode CE1 and the second connection electrode CE2.

However, the first concave portion CE1a and the first convex portion CE2a extending in the first direction DR1 are disposed in the second-second sub-pixel SP2b, such that the second light-emitting element 130, the first connection electrode CE1, and the second connection electrode CE2 may be electrically connected. Because the first convex portion CE2a and the second contact hole CH2 extending in the first direction DR1 are disposed in the second-second sub-pixel SP2b, the second contact hole CH2 and the second p-type electrode 135 of the second light-emitting element 130 may overlap each other even though the second light-emitting element 130 is partially shifted in the first direction DR1. Further, since the second contact hole CH2 has a larger size than the second p-type electrode 135, even if the second p-type electrode 135 is partially shifted, the second p-type electrode 135 can be easily exposed in an area of the second contact hole CH2. Because the first contact holes CH1, which are disposed at two opposite sides of the first concave portion CE1a, also extend in the first direction DR1, at least a part of the second n-type electrode 134 of the second light-emitting element 130 may overlap the first contact hole CH1. Therefore, in the second-second sub-pixel SP2b having the first concave portion CE1a and the first convex portion CE2a extending in the direction identical to the shift direction of the second light-emitting element 130, the second light-emitting element 130, the first connection electrode CE1, and the second connection electrode CE2 may be connected.

With reference to FIG. 7C, during the process of transferring the light-emitting element LED, an alignment error may occur, and the light-emitting element LED may be shifted from the exact position in the second direction DR2. In this case, in the concave portions CE1a and CE1b and the convex portions CE2a and CE2b extending in the direction identical to the shift direction of the second light-emitting element 130, at least a part of the first contact hole CH1 and at least a part of the second contact hole CH2 may overlap the second n-type electrode 134 and the second p-type electrode 135 of the second light-emitting element 130 and electrically connect the first connection electrode CE1 and the second connection electrode CE2 to the second light-emitting element 130.

For example, the second concave portion CE1b and the second convex portion CE2b extending in the second direction DR2 are disposed in the second-first sub-pixel SP2a. Because the second convex portion CE2b and the second contact hole CH2 are disposed while extending in the second direction DR2, the second contact hole CH2 and at least a part of the second p-type electrode 135 of the second light-emitting element 130 may overlap each other even though the second light-emitting element 130 is shifted in the second direction DR2. Because the first contact hole CH1 also extends in the second direction DR2, at least a part of the second n-type electrode 134 of the second light-emitting element 130 may overlap the first contact hole CH1. Therefore, in the second-first sub-pixel SP2a having the second concave portion CE1b and the second convex portion CE2b extending in the direction identical to the shift direction of the second light-emitting element 130, the second light-emitting element 130, the first connection electrode CE1, and the second connection electrode CE2 may be normally connected.

In contrast, because the first concave portion CE1a and the first convex portion CE2a, which are disposed in the first direction DR1, are disposed in the second-second sub-pixel SP2b, the second light-emitting element 130 shifted in the second direction DR2 may be misaligned with the first contact hole CH1 and the second contact hole CH2.

Therefore, in the display device 100 according to the exemplary aspects of the present specification, even though the light-emitting element LED is misaligned, the light-emitting element LED, the first connection electrode CE1, and the second connection electrode CE2 are connected, and an image may be normally displayed in at least one of the pair of sub-pixels SP that displays the same color. For example, the first convex portion CE2a of the second connection electrode CE2 and the first concave portion CE1a of the first connection electrode CE1 may extend in the first direction DR1 and be connected to the light-emitting element LED shifted in the first direction DR1. Further, the second convex portion CE2b of the second connection electrode CE2 and the second concave portion CE1b of the first connection electrode CE1 may extend in the second direction DR2 and be connected to the light-emitting element LED shifted in the second direction DR2. Therefore, in each of the pair of sub-pixels SP that displays the same color, the concave portions CE1a and CE1b and the convex portions CE2a and CE2b of the first connection electrode CE1 and the second connection electrode CE2 are disposed in different directions. Therefore, even though the light-emitting element LED is shifted and transferred the light-emitting element LED, the first connection electrode CE1, and the second connection electrode CE2 may be connected in at least any one of the sub-pixels SP.

In some examples, in the display device 100 according to the exemplary aspects of the present specification, the plurality of light-emitting elements LED may be self-assembled onto an assembling substrate 10 first, and then the self-assembled light-emitting element LED may be transferred to the display panel PN, such that the display device 100 may be produced. In this case, during the process of self-assembling the light-emitting element LED, the self-assembling may be performed by aligning the plurality of light-emitting elements LED so that the plurality of light-emitting elements LED corresponds to the disposition directions of the concave portions CE1a and CE1b of the first connection electrode CE1 and the convex portions CE2a and CE2b of the second connection electrode CE2. In particular, the second light-emitting element 130 and the third light-emitting element 140, which each have an elliptical planar shape, need to be aligned to correspond to the disposition directions of the concave portions CE1a and CE1b of the first connection electrode CE1 and the convex portions CE2a and CE2b of the second connection electrode CE2 on the display panel PN so that the second light-emitting element 130 and the third light-emitting element 140 may be electrically connected to the first connection electrode CE1 and the second connection electrode CE2. Therefore, the disposition directions of assembling electrodes AE of the assembling substrate 10 may be differently configured, and the plurality of light-emitting elements LED may be aligned in different directions and self-assembled.

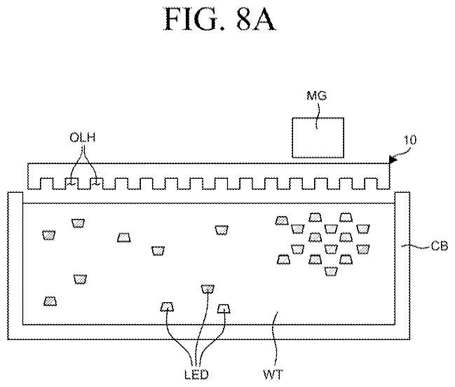

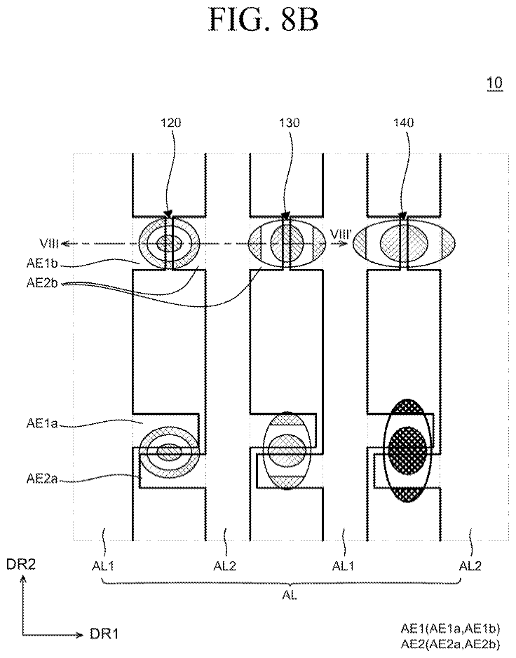

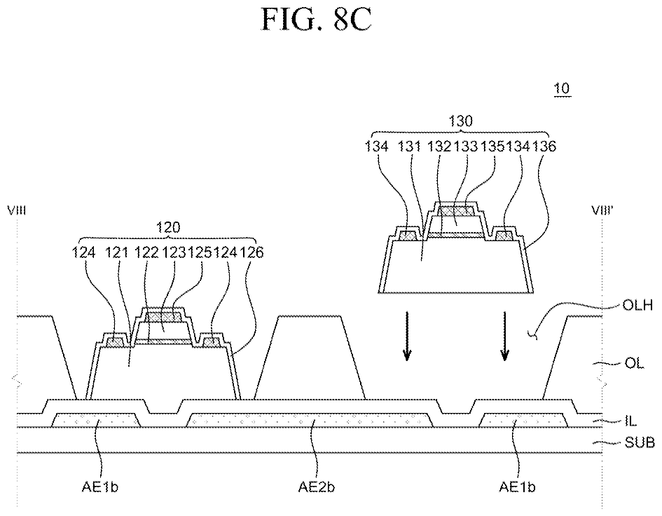

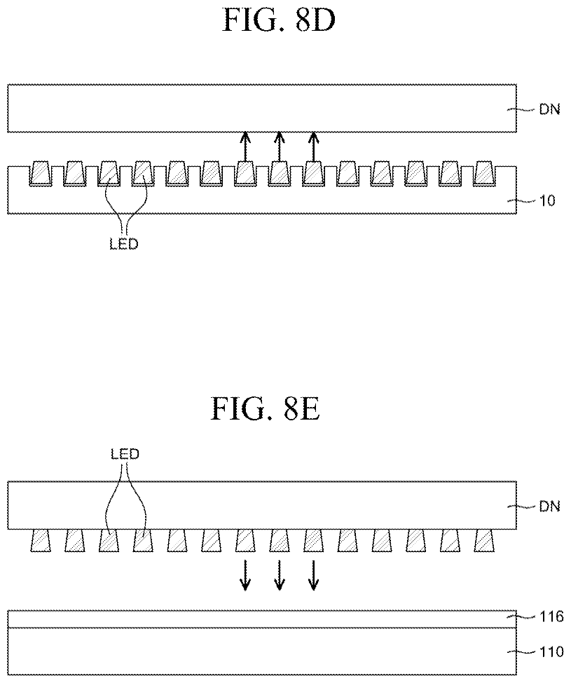

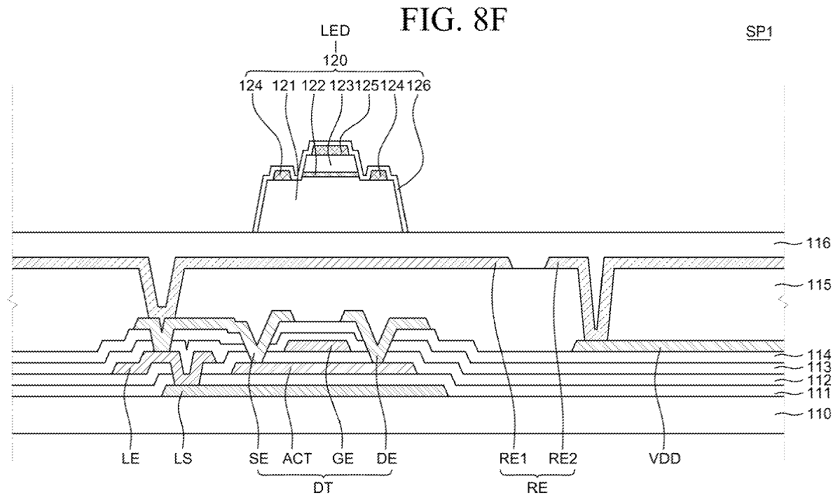

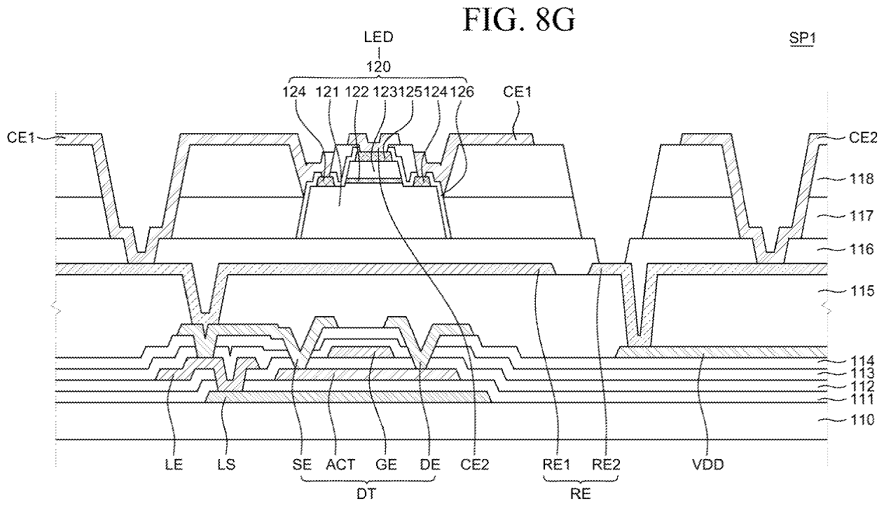

Hereinafter, a method of manufacturing the display device 100 according to the exemplary aspects of the present specification will be described with reference to FIGS. 8A to 8G.

FIGS. 8A to 8G are process diagrams for explaining a method of manufacturing the display device according to some aspects of the present disclosure. FIGS. 8A to 8C are process diagrams for explaining a process of self-assembling the plurality of light-emitting elements LED. FIGS. 8D to 8G are process diagrams for explaining a process of transferring the plurality of light-emitting elements LED and a process of forming the first connection electrode CE1 and the second connection electrode CE2.

With reference to FIG. 8A, the light-emitting element LED may be transferred to the assembling substrate 10 by a self-assembling method.

First, the plurality of light-emitting elements LED grown on a wafer is inputted to a chamber CB filled with a fluid WT. The fluid WT may include water or the like, and the chamber CB filled with the fluid WT may have a shape opened at an upper side thereof.

Next, the assembling substrate 10 may be positioned on the chamber CB filled with the light-emitting elements LED. The assembling substrate 10 is the substrate 110 on which the light-emitting element LED is temporarily self-assembled. After the light-emitting element LED is self-assembled on the assembling substrate 10, the light-emitting element LED on the assembling substrate 10 may be transferred to the display device 100.

Next, a magnet MG may be positioned on the assembling substrate 10. The light-emitting elements LED, which are submerged or suspended on a bottom of the chamber CB, may be moved toward the assembling substrate 10 by a magnetic force of the magnet MG.

In this case, the light-emitting element LED may include a magnetic element so that the light-emitting element LED may be moved by a magnetic field. For example, any one of the n-type electrodes 124, 134, and 144 or the p-type electrodes 125, 135, and 145 of the light-emitting element LED may include ferromagnetic materials such as iron (Fe), cobalt (Co), or nickel (Ni), such that a direction of the light-emitting element LED directed toward the magnet MG may be aligned.

Next, the light-emitting element LED, which has been moved toward the assembling substrate 10 by the magnet MG, may be self-assembled to the assembling substrate 10 by an electric field formed by a plurality of assembling lines AL and a plurality of assembling electrodes AE.

Specifically, with reference to FIGS. 8B and 8C, the assembling substrate 10 includes an assembly substrate SUB, the plurality of assembling lines AL, the plurality of assembling electrodes AE, an assembling insulating layer IL, and an organic layer OL.

First, the plurality of assembling lines AL and the plurality of assembling electrodes AE are disposed on the assembly substrate SUB. The plurality of assembling lines AL includes a plurality of first assembling lines AL1 and a plurality of second assembling lines AL2. The plurality of first assembling lines AL1 and the plurality of second assembling lines AL2 may be disposed to be spaced apart from one another at predetermined intervals.

The plurality of assembling electrodes AE includes a plurality of first assembling electrodes AE1 and a plurality of second assembling electrodes AE2. The plurality of first assembling electrodes AE1 may be connected to the plurality of first assembling lines AL1, and the plurality of second assembling electrodes AE2 may be connected to the plurality of second assembling lines AL2. The pair of first and second assembling electrodes AE1 and AE2 may be disposed adjacent to each other and form an electric field for self-assembling the light-emitting element LED. In the plurality of sub-pixels SP, the pair of first and second assembling electrodes AE1 and AE2 may be disposed to the exact position to which the light-emitting element LED is transferred.

The assembling insulating layer IL is disposed on the plurality of assembling lines AL and the plurality of assembling electrodes AE. The assembling insulating layer IL may protect the plurality of assembling lines AL from the fluid WT, thereby suppressing a defect such as corrosion of the plurality of assembling lines AL.

The organic layer OL including a plurality of pockets OLH is disposed on the assembling insulating layer IL. Each of the plurality of pockets OLH, which is formed by opening a part of the organic layer OL, may be an area in which the plurality of light-emitting elements LED is self-assembled. The plurality of pockets OLH may be disposed to overlap an area between the pair of first and second assembling electrodes AE1 and AE2. Thereafter, the plurality of pockets OLH may each be formed at positions respectively corresponding to the plurality of sub-pixels SP of the display device 100. The plurality of pockets OLH may be disposed to respectively correspond to the plurality of sub-pixels SP in a one-to-one manner. The light-emitting elements LED self-assembled in the plurality of pockets OLH may be transferred to the plurality of sub-pixels SP without change. The planar shape of the plurality of pockets OLH may correspond to the planar shape of the plurality of light-emitting elements LED. For example, the plurality of pockets OLH may include a pocket OLH having a circular planar shape corresponding to the first light-emitting element 120, a pocket OLH having an elliptical planar shape corresponding to the second light-emitting element 130, and a pocket OLH having an elliptical planar shape corresponding to the third light-emitting element 140.

Further, the plurality of light-emitting elements LED may be self-assembled in the pockets OLH of the organic layer OL by applying voltages to the plurality of assembling lines AL and the plurality of assembling electrodes AE. For example, an electric field may be formed by applying alternating current voltages to the plurality of first assembling lines AL1, the plurality of first assembling electrodes AE1, the plurality of second assembling lines AL2, and the plurality of second assembling electrodes AE2. The light-emitting element LED may have a polarity by being dielectrically polarized by the electric field. Further, the dielectrically polarized light-emitting element LED may be fixed or moved in a particular direction by dielectrophoresis (DEP). i.e., the electric field. Therefore, the plurality of light-emitting elements LED may be temporarily self-assembled inside the pockets OLH of the assembling substrate 10 by using the dielectrophoresis.

In this case, the alignment direction of the plurality of light-emitting elements LED may be adjusted by using the disposition direction of the first assembling electrode AE1 and the second assembling electrode AE2. In particular, the alignment direction of the second light-emitting element 130, which includes the pair of second n-type electrodes 134 disposed at two opposite ends of the second n-type semiconductor layer 131, and the third light-emitting element 140, which includes the pair of third n-type electrodes 144 disposed at two opposite ends of the third n-type semiconductor layer 141, may be changed depending on the disposition direction of the first assembling electrode AE1 and the second assembling electrode AE2.

With reference to FIG. 8B, the first assembling electrode AE1 includes a first-first assembling electrode AE1a and a first-second assembling electrode AE1b, and the second assembling electrode AE2 includes a second-first assembling electrode AE2a and a second-second assembling electrode AE2b. The first-first assembling electrode AE1a and the second-first assembling electrode AE2a may be disposed adjacent to each other at a predetermined interval, and the first-second assembling electrode AE1b and the second-second assembling electrode AE2b may be disposed adjacent to each other at a predetermined interval.

The first-first assembling electrode AE1a and the second-first assembling electrode AE2a extend in the first direction DR1 and are disposed in a staggered manner in the second direction DR2. The first-first assembling electrode AE1a extends in the first direction DR1 toward the second assembling line AL2 adjacent to the first-first assembling electrode AE1a. The second-first assembling electrode AE2a extends in the first direction DR1 toward the first assembling line AL1 adjacent to the second-first assembling electrode AE2a. However, the first-first assembling electrode AE1a and the second-first assembling electrode AE2a extend in a staggered manner, such that the first-first assembling electrode AE1a and the second-first assembling electrode AE2a may face each other in the second direction DR2. For example, in case that the second direction DR2 is a vertical direction, the second-first assembling electrode AE2a may be disposed at an upper or lower side of the first-first assembling electrode AE1a. Therefore, the first-first assembling electrode AE1a and the second-first assembling electrode AE2a, which are disposed in a staggered manner in the second direction DR2, may be disposed adjacent to each other while having a gap extending in the first direction DR1.

The first-second assembling electrode AE1b and the second-second assembling electrode AE2b may face each other while extending in the first direction DR1. The first-second assembling electrode AE1b and the second-second assembling electrode AE2b may extend on the same line toward each other. Therefore, an end of the first-second assembling electrode AE1b and an end of the second-second assembling electrode AE2b may face each other in the first direction DR1. The first-second assembling electrode AE1b and the second-second assembling electrode AE2b may be disposed adjacent to each other while having a gap extending in the second direction DR2.

In this case, the second light-emitting element 130 may be self-assembled so that the pair of second n-type electrodes 134 is respectively directed toward the first and second assembling electrodes AE1 and AE2 disposed adjacent to each other. For example, one second n-type electrode 134 of the pair of second n-type electrodes 134 may be disposed toward the first assembling electrode AE1. The other second n-type electrode 134 may be disposed toward the second assembling electrode AE2 most adjacent to the first assembling electrode AE1.

In this case, in the second light-emitting element 130 self-assembled on the first-first assembling electrode AE1a and the second-first assembling electrode AE2a, which face each other in the second direction DR2, the pair of second n-type electrodes 134 may be aligned in the second direction DR2. Because one second n-type electrode 134 is aligned toward the first-first assembling electrode AE1a and the other second n-type electrode 134 is aligned toward the second-first assembling electrode AE2a, the pair of second n-type electrodes 134 may be aligned in the second direction DR2 with the second p-type electrode 135 interposed therebetween. That is, the major axis of the second n-type semiconductor layer 131 of the second light-emitting element 130 may be aligned in the second direction DR2.

In contrast, in the second light-emitting element 130 self-assembled on the first-second assembling electrode AE1b and the second-second assembling electrode AE2b, which face each other in the first direction DR1, the pair of second n-type electrodes 134 may be aligned in the first direction DR1. Because one second n-type electrode 134 is aligned toward the first-second assembling electrode AE1b and the other second n-type electrode 134 is aligned toward the second-second assembling electrode AE2b, the pair of second n-type electrodes 134 may be aligned in the first direction DR1 with the second p-type electrode 135 interposed therebetween. That is, the major axis of the second n-type semiconductor layer 131 of the second light-emitting element 130 may be aligned in the first direction DR1.

Therefore, the alignment positions of the second n-type electrodes 134 disposed at two opposite ends of the second light-emitting element 130 in accordance with the arrangement positions of the first assembling electrode AE1 and the second assembling electrode AE2. The first-first assembling electrode AE1a and the second-first assembling electrode AE2a, which face each other in the second direction DR2, may be formed and aligned so that the pair of second n-type electrodes 134 is disposed in the second direction DR2, and the second light-emitting element 130 may be self-assembled. Likewise, the first-second assembling electrode AE1b and the second-second assembling electrode AE2b, which face each other in the first direction DR1, may be formed and aligned so that the pair of second n-type electrodes 134 is disposed in the first direction DR1, and the second light-emitting element 130 may be self-assembled. Further, the alignment direction of the third light-emitting element 140, which includes the pair of third n-type electrodes 144 disposed at two opposite ends of the third n-type semiconductor layer 141, may be adjusted in the same way as the second light-emitting element 130.

Next, with reference to FIG. 8D, the plurality of light-emitting elements LED of the assembling substrate 10 is transferred to a donor DN.

First, the assembling substrate 10 and the donor DN are aligned so that the plurality of light-emitting elements LED and the donor DN face one another. Further, the assembling substrate 10 and the donor DN may be joined, such that an upper portion of the light-emitting element LED may be in contact with the donor DN. In this case, the donor DN is made of a material having an adhesive force, such that the upper portions of the plurality of light-emitting elements LED may be bonded to the donor DN and transferred to the donor DN from the assembling substrate 10. The donor DN may be made of a polymer material having viscoelasticity, e.g., polydimethylsiloxane (PDMS), polyurethane acrylate (PUA), polyethylene glycol (PEG), polymethylmethacrylate (PMMA), polystyrene (PS), epoxy resin, urethane resin, acrylic resin, or the like. However, the present disclosure is not limited thereto.

Next, with reference to FIGS. 8E and 8F, the plurality of light-emitting elements LED on the donor DN is transferred onto the bonding layer 116 of the display panel PN.

The donor DN and the display device 100 formed with the bonding layer 116 are aligned. The display device 100 and the donor DN may be aligned so that the plurality of light-emitting elements LED of the donor DN and the bonding layer 116 of the display device 100 face one another. Further, the donor DN and the display device 100 may be joined, such that the light-emitting element LED on the donor DN may be transferred onto the bonding layer 116.

In this case, a bonding force between the bonding layer 116 and the light-emitting element LED is higher than a bonding force between the donor DN and the light-emitting element LED, such that the light-emitting element LED may be detached from the donor DN and attached to the bonding layer 116.

Therefore, the plurality of light-emitting elements LED may be self-assembled to be arranged on the assembling substrate 10 while corresponding to the plurality of sub-pixels SP, and then the plurality of light-emitting elements LED on the assembling substrate 10 may be transferred to the display device 100 by using the donor DN. In this case, it is possible to omit the process of transferring the plurality of light-emitting elements LED to the donor DN from the wafer after aligning the plurality of light-emitting elements LED so that the plurality of light-emitting elements LED corresponds to the intervals between the plurality of sub-pixels SP. The light-emitting element LED may be easily self-assembled at an exact position by using an electric field. Therefore, the plurality of light-emitting elements LED on the wafer is self-assembled by using the assembling substrate 10, which may minimize an alignment error and simplify the process of transferring the plurality of light-emitting elements LED.

In the present specification, the configuration has been described in which the plurality of light-emitting elements LED is self-assembled to the assembling substrate 10 by the self-assembling method and then transferred to the display device 100 by using the donor DN. However, the present disclosure is not limited thereto. For example, a separate assembling line AL may be formed on the display device 100, and the plurality of light-emitting elements LED may be self-assembled directly on the display device 100. However, the present disclosure is not limited thereto.

Next, with reference to FIGS. 8F and 8G, the light-emitting element LED is transferred onto the bonding layer 116 of the display device 100, and then the first connection electrode CE1 and the second connection electrode CE2 are formed, such that the light-emitting element LED may be electrically connected to the driving transistor DT and the power line VDD.

First, the second planarization layer 117 and the third planarization layer 118, which cover the plurality of light-emitting elements LED, are formed. Further, the contact holes, through which the n-type electrodes 124, 134, and 144 and the p-type electrodes 125, 135, and 145 of the plurality of light-emitting elements LED are exposed, may be formed in the third planarization layer 118. The contact holes, through which the first reflective electrode RE1 and the reflective electrode RE are exposed, may be formed in the third planarization layer 118, the second planarization layer 117, and the bonding layer 116.

Next, the first connection electrode CE1 and the second connection electrode CE2 may be formed on the third planarization layer 118. Further, an electrically conductive material layer may be formed on the front surface of the substrate 110, and the first connection electrode CE1 and the second connection electrode CE2 may be formed by patterning the electrically conductive material layer.

Therefore, in the display device 100 and the method of manufacturing the display device 100 according to the exemplary aspects of the present specification, the self-assembling may be performed by adjusting the alignment directions of the second light-emitting element 130 and the third light-emitting element 140, which each have an elliptical shape, in accordance with the arrangement positions of the first assembling electrode AE1 and the second assembling electrode AE2. The alignment positions of the second n-type electrodes 134, which are disposed at two opposite ends of the second light-emitting element 130, or the alignment positions of the third n-type electrodes 144, which are disposed at two opposite ends of the third light-emitting element 140, may be adjusted in accordance with the positions of the first assembling electrode AE1 and the second assembling electrode AE2. For example, the first-first assembling electrode AE1a and the second-first assembling electrode AE2a, which face each other in the second direction DR2, may be formed and aligned so that the pair of second n-type electrodes 134 and the pair of third n-type electrodes 144 are disposed in the second direction DR2, and the second light-emitting element 130 and the third light-emitting element 140 may be self-assembled. The first-second assembling electrode AE1b and the second-second assembling electrode AE2b, which face each other in the first direction DR1, may be formed and aligned so that the pair of second n-type electrodes 134 and the pair of third n-type electrodes 144 are disposed in the first direction DR1, and the second light-emitting element 130 and the third light-emitting element 140 may be self-assembled. Therefore, the first assembling electrode AE1 and the second assembling electrode AE2 may face each other in any one of the first direction DR1 and the second direction DR2 and be aligned so that the directions of the second light-emitting element 130 and the third light-emitting element 140, which each have an elliptical shape, correspond to the disposition directions of the concave portions CE1a and CE1b of the first connection electrode CE1 and the convex portions CE2a and CE2b of the second connection electrode CE2, and the self-assembling may be performed.

The exemplary embodiments of the present disclosure may also be described as follows:

According to an aspect of the present disclosure, there is provided a display device. The display device includes a substrate having pixels each comprising a plurality of sub-pixels, a plurality of light-emitting elements disposed on the plurality of sub-pixels and each comprising one or more n-type electrodes and a p-type electrode, a first connection electrode disposed on each of the plurality of light-emitting elements of the plurality of sub-pixels and comprising a concave portion that overlaps the p-type electrode, and a second connection electrode disposed on each of the plurality of light-emitting elements of the plurality of sub-pixels and comprising a convex portion that overlaps the p-type electrode, the concave portion and the convex portion extend in a first direction in each of some of the plurality of sub-pixels among the plurality of sub-pixels, and the concave portion and the convex portion extend in a second direction different from the first direction in each of the remaining sub-pixels among the plurality of sub-pixels.

The pixel may include a pair of first sub-pixels comprising a first-first sub-pixel and a first-second sub-pixel, a pair of second sub-pixels comprising a second-first sub-pixel and a second-second sub-pixel, and a pair of third sub-pixels comprising a third-first sub-pixel and a third-second sub-pixel, and the concave portions may extend in different direction in each of the pair of first sub-pixels, each of the pair of second sub-pixels, and each of the pair of third sub-pixels.

The concave portion may extend in the first direction in any one of the first-first sub-pixel and the first-second sub-pixel, the concave portion may extend in the first direction in any one of the second-first sub-pixel and the second-second sub-pixel, and the concave portion may extend in the first direction in any one of the third-first sub-pixel and the third-second sub-pixel.

The concave portion and the convex portion may extend in the second direction in each of the first-first sub-pixel, the second-first sub-pixel, and the third-first sub-pixel, and the concave portion and the convex portion may extend in the first direction in each of the first-second sub-pixel, the second-second sub-pixel, and the third-second sub-pixel.

Each of the plurality of light-emitting elements may further include an n-type semiconductor layer having a top surface on which the n-type electrode is disposed, a light-emitting layer disposed on the n-type semiconductor layer, and a p-type semiconductor layer disposed on the light-emitting layer and having a top surface on which the p-type electrode is disposed. In each of some of the plurality of light-emitting elements, the top surface of the n-type semiconductor layer may have an elliptical shape, and the n-type electrodes may be disposed at two opposite ends of the top surface of the n-type semiconductor layer in a major axis direction.

A minor axis of the top surface of the n-type semiconductor layer of each of some of the light-emitting elements may be disposed in a direction identical to extension directions of the concave portion and the convex portion corresponding to some of the light-emitting elements, and a major axis of the top surface of the n-type semiconductor layer on each of some of the light-emitting elements may be disposed in a direction different from the extension directions of the concave portion and the convex portion corresponding to some of the light-emitting elements.

A major axis of the top surface of the n-type semiconductor layer may be disposed in the second direction in the light-emitting element that overlaps the concave portion and the convex portion extending in the first direction among some of the light-emitting elements.

The display device may further include an insulating layer disposed between the plurality of light-emitting elements and the first connection electrode and between the plurality of light-emitting elements and the second connection electrode. The insulating layer may include a pair of first contact holes that overlaps the n-type electrode and the first connection electrode of each of the plurality of light-emitting elements, and a second contact hole that overlaps the p-type electrode and the second connection electrode of each of the plurality of light-emitting elements.

The concave portion of the first connection electrode may be disposed between the pair of first contact holes, and the second contact hole may overlap the convex portion of the second connection electrode.

According to an aspect of the present disclosure, there is provided a method of manufacturing a display device. The method includes self-assembling a plurality of light-emitting elements on an assembling substrate on which a plurality of assembling electrodes is formed, transferring the plurality of light-emitting elements on the assembling substrate to a donor, and transferring the plurality of light-emitting elements of the donor to a plurality of sub-pixels of a display panel. The self-assembling of the plurality of light-emitting elements comprises forming an electric field by applying voltages to the plurality of assembling electrodes, and self-assembling the plurality of light-emitting elements on the plurality of assembling electrodes with the electric field.

The plurality of assembling electrodes may include a plurality of first assembling electrodes extending in a first direction and comprising a first-first assembling electrode and a first-second assembling electrode, and a plurality of second assembling electrodes extending in the first direction and comprising a second-first assembling electrode disposed adjacent to the first-first assembling electrode, and a second-second assembling electrode disposed adjacent to the first-second assembling electrode. The first-first assembling electrode and the second-first assembling electrode may be disposed in a staggered manner such that a gap extending in the first direction is formed between the first-first assembling electrode and the second-first assembling electrode, and the first-second assembling electrode may be disposed to face the second-second assembling electrode such that a gap extending in a second direction perpendicular to the first direction is formed between the first-second assembling electrode and the second-second assembling electrode.

Each of some of the plurality of light-emitting elements may include an n-type semiconductor layer having a top surface having an elliptical shape, a pair of n-type electrodes disposed at two opposite ends of the n-type semiconductor layer in a major axis direction on a top surface of the n-type semiconductor layer, a light-emitting layer disposed on the n-type semiconductor layer, a p-type semiconductor layer disposed on the light-emitting layer, and a p-type electrode disposed on the p-type semiconductor layer, and the self-assembling of some of the light-emitting elements may include performing self-assembling so that one of the pair of n-type electrodes overlaps the plurality of first assembling electrodes, and the other n-type electrode overlaps the plurality of second assembling electrodes.

The pair of n-type electrodes may be aligned in the second direction in each of some of the light-emitting elements that are assembled on the first-first assembling electrode and the second-first assembling electrode, and the pair of n-type electrodes may be aligned in the first direction in each of some of the light-emitting elements that are self-assembled on the first-second assembling electrode and the second-second assembling electrode.

Although the exemplary embodiments of the present disclosure have been described in detail with reference to the accompanying drawings, the present disclosure is not limited thereto and may be embodied in many different forms without departing from the technical concept of the present disclosure. Therefore, the exemplary embodiments of the present disclosure are provided for illustrative purposes only but not intended to limit the technical concept of the present disclosure. The scope of the technical concept of the present disclosure is not limited thereto. Therefore, it should be understood that the above-described exemplary embodiments are illustrative in all aspects and do not limit the present disclosure.

Claim language or other language reciting “at least one of” a set and/or “one or more” of a set indicates that one member of the set or multiple members of the set (in any combination) satisfy the claim. For example, claim language reciting “at least one of A and B” or “at least one of A or B” means A, B, or A and B. In another example, claim language reciting “at least one of A, B, and C” or “at least one of A, B, or C” means A, B, C, or A and B, or A and C, or B and C, or A and B and C. The language “at least one of” a set and/or “one or more” of a set does not limit the set to the items listed in the set. For example, claim language reciting “at least one of A and B” or “at least one of A or B” can mean A, B, or A and B, and can additionally include items not listed in the set of A and B.

What is claimed is:

1. A display device comprising:
a substrate having pixels each including a plurality of sub-pixels;
a plurality of light-emitting elements on the plurality of sub-pixels and each including one or more n-type electrodes and a p-type electrode;
a first connection electrode on each of the plurality of light-emitting elements of the plurality of sub-pixels and including a concave portion that overlaps the one or more n-type electrodes; and
a second connection electrode on each of the plurality of light-emitting elements of the plurality of sub-pixels and including a convex portion that overlaps the p-type electrode,
wherein the concave portion and the convex portion extend in a first direction in each of a first subset of the plurality of sub-pixels, and
wherein the concave portion and the convex portion extend in a second direction different from the first direction in each of a second subset of the plurality of sub-pixels.

2. The display device of claim 1, wherein each of the pixels comprises:
a pair of first sub-pixels including a first-first sub-pixel and a first-second sub-pixel;
a pair of second sub-pixels including a second-first sub-pixel and a second-second sub-pixel; and
a pair of third sub-pixels including a third-first sub-pixel and a third-second sub-pixel,
wherein the concave portions extend in different direction in the pair of first sub-pixels, the pair of second sub-pixels, and the pair of third sub-pixels.

3. The display device of claim 2, wherein
the concave portion extends in the first direction in any one of the first-first sub-pixel and the first-second sub-pixel,
the concave portion extends in the first direction in any one of the second-first sub-pixel and the second-second sub-pixel, and
the concave portion extends in the first direction in any one of the third-first sub-pixel and the third-second sub-pixel.

4. The display device of claim 2, wherein the concave portion and the convex portion extend in the second direction in each of the first-first sub-pixel, the second-first sub-pixel, and the third-first sub-pixel, and
wherein the concave portion and the convex portion extend in the first direction in each of the first-second sub-pixel, the second-second sub-pixel, and the third-second sub-pixel.

5. The display device of claim 2, wherein each of the plurality of light-emitting elements further comprises:
an n-type semiconductor layer having a top surface on which the n-type electrode is disposed;
a light-emitting layer on the n-type semiconductor layer; and
a p-type semiconductor layer on the light-emitting layer and having a top surface on which the p-type electrode is disposed,
wherein in each of a subset of the plurality of light-emitting elements, the top surface of the n-type semiconductor layer has an elliptical shape, and the n-type electrodes are disposed at two opposite ends of the top surface of the n-type semiconductor layer in a major axis direction.

6. The display device of claim 5, wherein a minor axis of the top surface of the n-type semiconductor layer of each of the subset of the light-emitting elements is disposed in a direction identical to extension directions of the concave portion and the convex portion corresponding to the subset of the light-emitting elements, and
wherein a major axis of the top surface of the n-type semiconductor layer on each of the subset of the light-emitting elements is disposed in a direction different from the extension directions of the concave portion and the convex portion corresponding to the subset of the light-emitting elements.

7. The display device of claim 5, wherein a major axis of the top surface of the n-type semiconductor layer is disposed in the second direction in the light-emitting element that overlaps the concave portion and the convex portion extending in the first direction among the subset of the light-emitting elements.

8. The display device of claim 5, further comprising:
an insulating layer between the plurality of light-emitting elements and the first connection electrode and between the plurality of light-emitting elements and the second connection electrode,
wherein the insulating layer includes a pair of first contact holes that overlaps the n-type electrode and the first connection electrode of each of the plurality of light-emitting elements; and
a second contact hole that overlaps the p-type electrode and the second connection electrode of each of the plurality of light-emitting elements.

9. The display device of claim 8, wherein the concave portion of the first connection electrode is between the pair of first contact holes, and the second contact hole overlaps the convex portion of the second connection electrode.

10. A method of manufacturing a display device, the method comprising:
self-assembling a plurality of light-emitting elements on an assembling substrate on which a plurality of assembling electrodes is formed;
transferring the plurality of light-emitting elements on the assembling substrate to a donor; and
transferring the plurality of light-emitting elements of the donor to a plurality of sub-pixels of a display panel,
wherein the self-assembling of the plurality of light-emitting elements includes forming an electric field by applying voltages to the plurality of assembling electrodes, and self-assembling the plurality of light-emitting elements on the plurality of assembling electrodes with the electric field.

11. The method of claim 10, wherein the plurality of assembling electrodes comprises:
a plurality of first assembling electrodes extending in a first direction and including a first-first assembling electrode and a first-second assembling electrode; and
a plurality of second assembling electrodes extending in the first direction and including a second-first assembling electrode disposed adjacent to the first-first assembling electrode, and a second-second assembling electrode disposed adjacent to the first-second assembling electrode,
wherein the first-first assembling electrode and the second-first assembling electrode are disposed in a staggered manner such that a gap extending in the first direction is formed between the first-first assembling electrode and the second-first assembling electrode, and
wherein the first-second assembling electrode is disposed to face the second-second assembling electrode such that a gap extending in a second direction perpendicular to the first direction is formed between the first-second assembling electrode and the second-second assembling electrode.

12. The method of claim 11, wherein each of a subset of the plurality of light-emitting elements comprises:
an n-type semiconductor layer having a top surface with an elliptical shape;
a pair of n-type electrodes at two opposite ends of the n-type semiconductor layer in a major axis direction on a top surface of the n-type semiconductor layer;
a light-emitting layer on the n-type semiconductor layer;
a p-type semiconductor layer on the light-emitting layer;
a p-type electrode on the p-type semiconductor layer, and
wherein the self-assembling of the subset of the light-emitting elements includes performing self-assembling so that one of the pair of n-type electrodes overlaps the plurality of first assembling electrodes, and the other one of the pair of n-type electrodes overlaps the plurality of second assembling electrodes.

13. The method of claim 12, wherein the pair of n-type electrodes is aligned in the second direction in each of some of the light-emitting elements that are assembled on the first-first assembling electrode and the second-first assembling electrode, and
wherein the pair of n-type electrodes is aligned in the first direction in each of the subset of the light-emitting elements that are self-assembled on the first-second assembling electrode and the second-second assembling electrode.

14. The method of claim 10, wherein a shape of each of the plurality of light emitting elements corresponds to a shape of each of a plurality of holes in the assembling substrate.

15. A display device comprising:
a substrate including a plurality of sub-pixels;
a plurality of light-emitting elements on the plurality of sub-pixels and each including one or more n-type electrodes and a p-type electrode; and
a first connection electrode overlapping the one or more n-types electrodes, and a second connection electrode overlapping the p-type electrode on each of the plurality of light-emitting elements,
wherein the second connection electrode overlaps the p-type electrode in different directions in at least two of the plurality of sub-pixels.

16. The display device of claim 15, wherein the first connection electrode and the second connection electrode have a U-shape where the first connection electrode and the second connection electrode overlap the p-type electrode on each of the plurality of light-emitting elements.

17. The display device of claim 15, wherein the plurality of sub-pixels are paired and the p-type electrode in each sub-pixel in a given pair of sub-pixels is overlapped in one of the different directions.

18. The display device of claim 15, wherein the p-type electrode in at least two adjacent sub-pixels are overlapped in a same direction.

19. The display device of claim 15, wherein the p-type electrode in any two adjacent sub-pixels of the plurality of sub-pixels are overlapped in the different directions.

20. The display device of claim 15, wherein the plurality of sub-pixels are paired and a light emitting element on sub-pixels of each pair of sub-pixels has a same number of n-type electrodes.

21. The display device of claim 20, wherein when the sub-pixels of a given pair of sub-pixels has two n-type electrodes, the two n-type electrodes in a first one of the sub-pixels of the given pair are oriented in a first direction and the two-n-type electrodes in a second one of the sub-pixels of the given pair are oriented in a second direction that is different from the first direction.

22. The display device of claim 21, wherein the first direction and the second direction are different than a respective one of the different directions in which the first connection electrode and the second connection electrode overlap the p-type electrode in the first one of the sub-pixels and the second one of the sub-pixels.

23. The display device of claim 15, wherein the one or more n-type electrodes have one of a circular shape or an elliptical shape.

24. The display device of claim 15, further comprising:
a light-emitting layer between the one or more n-type electrodes and the p-type electrode of each of the plurality of light emitting-elements.

25. The display device of claim 15, wherein the one or more n-type electrodes and the p-type electrode are electrically connected.

26. The display device of claim 15, wherein each of the one or more n-type electrodes can have one a circular shape or an elliptical shape.

27. The display device of claim 15, wherein the plurality of light emitting elements include a first light emitting element, a second light emitting element, and a third light emitting elements.

28. The display device of claim 27, wherein the first light emitting element has a circular shape.

29. The display device of claim 27, wherein the second light emitting element and the third light emitting element have an elliptical shape.

30. The display device of claim 15, further comprising:
a driving transistor; and
at least one insulating layer on the driving transistor.

31. The display device of claim 30, wherein the at least one insulating layer includes a first insulating portion and a second insulating portion separated by the first connection electrode.

32. The display device of claim 30, further comprising:
a bonding layer; and
a planarization layer, wherein the bonding layer and the planarization layer have a step-wise structure.
